(19) United States
(12) Patent Application Publication
(10) Pub. No.: US 2005/0012143 A1
(43) Pub. Date: Jan. 20, 2005

(54) Semiconductor device and method of manufacturing the same

(76) Inventors: Hideaki Tanaka, Yokosuka-shi (JP); Masakatsu Hoshi, Yokohama-shi (JP); Tetsuya Hayashi, Yokosuka-shi (JP); Saichirou Kaneko, Mukou-shi (JP)

Correspondence Address: MCDERMOTT WILL & EMERY LLP, 600 13th Street, N.W., Washington, DC, 20005-3096, US

(21) Appl. No.: 10/872,772

(22) Filed: Jun. 22, 2004

(30) Foreign Application Priority Data
Jun. 24, 2003 (JP) P 2003-178996
Jul. 29, 2003 (JP) P 2003-281463
Dec. 15, 2003 (JP) P 2003-416247

(51) Int. Cl. H01L 21/331

(52) U.S. Cl. 257/328; 257/77; 438/368

(57) ABSTRACT

An aspect of the present invention provides a semiconductor device that includes a semiconductor base including, a semiconductor substrate of a first conductivity type and a drain region of the first conductivity type formed on the semiconductor substrate and having a lower impurity concentration than the semiconductor substrate, a gate electrode insulated from the semiconductor base by a gate insulating film, the gate electrode made of a semiconductor material, a built-in potential difference between a region and the gate electrode made of the semiconductor material is greater than that of polysilicon having as high impurity concentration as possible, the region is a part of the drain region adjacent to the gate electrode through the gate insulating film.

### BACKGROUND OF THE INVENTION

The present invention relates to a semiconductor device and a method of manufacturing the same. An example of a planar power MOSFET semiconductor device is disclosed in Japanese Laid-Open Patent Publication No. Hei-10-308510. In this publication, the semiconductor device has an n⁺-type silicon carbide semiconductor substrate, an n⁻ type silicon carbide epitaxial layer formed on the substrate and having a lower impurity concentration than the substrate, a p⁻ type base region formed in a predetermined area at the surface of the epitaxial layer, and an n⁺-type source region formed in a predetermined area at the surface of the base region. At the surface of the base region, an n-type surface channel region is formed to connect the source region and epitaxial layer to each other. On the surface channel region, there is formed a gate insulating film on which a gate electrode is formed from p⁺-type polysilicon. In contact with the source region, a source electrode is formed. In contact with a back face of the silicon carbide substrate, a drain electrode is formed. The gate electrode is electrically insulated from the source electrode with an interlayer insulating film.

In this semiconductor device, a voltage is applied between the drain electrode and the source electrode, and a voltage is applied to the gate electrode to form an accumulation layer in the surface channel region under the gate insulating film. As a result, electrons flow from the source region through the surface channel region and silicon carbide epitaxial layer to the drain electrode.

Another semiconductor device is disclosed in Japanese Laid-Open Patent Publication No. Hei-6-252408. This semiconductor device has an n⁺-type substrate region, an n-type drain region, an n⁺-type source region, a p-type base region, and an insulated electrode. The insulated electrode is insulated from the drain region with an insulating film and is made of, for example, high-concentration p⁺-type polysilicon. A part of the drain region adjacent to the insulated electrode with the insulating film interposing between them is called a channel region. A drain electrode forms an ohmic contact with the substrate region. The source region and insulated electrode form each an ohmic contact with a source electrode. Namely, the insulated electrode is fixed at a source potential. The base region forms an ohmic contact with a base electrode.

Still another semiconductor device is disclosed in Japanese Laid-Open Patent Publication No. 2003-68759. This disclosure forms, on the same silicon carbide substrate, a junction field effect transistor serving as a switching element and a silicon carbide protective pn diode (using the rectifying characteristic of a pn junction) to protect the switching element. The protective pn diode may be used as a temperature sensor to provide a protective function when the switching element operates at high temperatures.

### SUMMARY OF THE INVENTION

The technique disclosed in the Japanese Laid-Open Patent Publication No. Hei-10-308510 involves an incomplete crystalline structure at an interface between the gate insulating film and the n⁻-type surface channel region. As a result, the accumulation layer formed by applying a voltage to the gate electrode contains a large amount of interface state serving as an electron trap. This raises a problem that channel mobility cannot be increased. To solve this problem, the impurity concentration of the surface channel region may be increased to lift the mobility. This MOSFET, however, realizes a normally OFF state when no voltage is applied to the gate electrode, by depleting the surface channel region with the use of a potential difference (built-in potential) among a work function φg at the p⁺-type polysilicon gate electrode, a work function φb at the p⁻-type base region, and a work function φc at the surface channel region. Accordingly, if the impurity concentration of the surface channel region is increased, it will be difficult to completely deplete the surface channel region. This may lead to establish a normally ON state.

According to the technique disclosed in the Japanese Laid-Open Patent Publication No. Hei-6-252408, the accuracy of processing limits a channel thickness, and therefore, there is a limit on improving cutoff performance by thinning the channel. On the other hand, according to the technique disclosed in the Japanese Laid-Open Patent Publication No. 2003-68759, the protective element serving as a temperature sensor is required to surely detect when the temperature of the switching element exceeds a predetermined level. This function of correctly detecting the temperature of the switching element must be secured without causing erroneous detection.

An aspect of the present invention provides a semiconductor device that includes a semiconductor base including, a semiconductor substrate of a first conductivity type and a drain region of the first conductivity type formed on the semiconductor substrate and having a lower impurity concentration than the semiconductor substrate, a gate electrode insulated from the semiconductor base by a gate insulating film, the gate electrode made of a semiconductor material, a built-in potential difference between a region and the gate electrode made of the semiconductor material is greater than that of polysilicon having as high impurity concentration as possible, the region is a part of the drain region adjacent to the gate electrode through the gate insulating film.

Another aspect of the present invention provides a semiconductor device that includes a semiconductor base including, a semiconductor substrate of a first conductivity type, and a drain region of the first conductivity type formed on the semiconductor substrate, the drain region having a lower impurity concentration than the semiconductor substrate, a base region of a second conductivity type formed on a surface of the drain region, a trench formed adjacent to the base region and reaching the drain region, a source region of the first conductivity type formed in a predetermined surface area of the base region and shallower than the base region, a surface channel region formed on an inner side face of the trench, to connect the source and drain regions to each other, a gate insulating film configured to insulate the semiconductor base from a gate electrode, the gate electrode formed on the gate insulating film adjacent to the surface channel region from a semiconductor material having a work function of 5.1 eV or over, a source electrode formed in contact with the base and source regions, and a drain electrode formed at a surface of the semiconductor base.

Still another aspect of the present invention provides a semiconductor device that includes a semiconductor base including a semiconductor substrate of a first conductivity type, and an epitaxial layer of a second conductivity type formed on the semiconductor substrate and having a lower impurity concentration than the semiconductor substrate, a source region of the first conductivity type formed on the epitaxial layer and being shallower than the epitaxial layer, a drain region of the first conductivity type formed on the epitaxial layer and being shallower than the epitaxial layer, a surface channel region formed to connect the source region and drain region to each other, a gate insulating film formed on the channel region, the gate insulating film configured to insulate the semiconductor base from a gate electrode, the gate electrode formed on the gate insulating film adjacent to the surface channel region from a semiconductor material having a work function of 5.1 eV or over, a source electrode formed in contact with the source region, and a drain electrode formed in contact with the drain region.

Still another aspect of the present invention provides a method of manufacturing a semiconductor device, the method that includes forming an epitaxial layer on a semiconductor substrate, forming a base region in a predetermined area of the epitaxial layer, forming a surface channel region in a predetermined area on the epitaxial layer and base region, forming a source region in a predetermined area of the base region, forming a gate insulating film on the source region and surface channel region, and forming a gate electrode on the gate insulating film adjacent to the surface channel region from a semiconductor material having a work function of 5.1 eV or over.

Still another aspect of the present invention a semiconductor device that includes a drain region of a first conductivity type, trenches formed in parallel with one another in a principal plane of a semiconductor base where the drain region is formed, a source region of the first conductivity type formed in contact with a part of the principal plane sandwiched between adjacent ones of the trenches, insulating films formed in each of the trenches, and insulated electrodes insulated from the drain region by the insulating film, wherein the insulated electrode is made of a semiconductor material, a built-in potential difference between a region and the insulated electrode made of the semiconductor material is greater than that of polysilicon having as high impurity concentration as possible, the region is a part of the drain region between the insulated electrodes.

Still another aspect of the present invention provides a semiconductor device that includes a switching unit including a part of a semiconductor base whose forbidden band gap is wider than silicon, the switching unit having at least three terminals, an insulating film formed on a surface of the semiconductor base, and a protection unit formed on the insulating film and configured to protect the switching unit, the protection unit made of a semiconductor material whose forbidden band gap is wider than silicon.

Still another aspect of the present invention provides a method of manufacturing a semiconductor device, the method that includes forming a drain region on a semiconductor base, forming a base region at a surface of the drain region by ion implantation, forming a source region in contact with the base region, forming a gate insulating film in contact with the source region, base region, and drain region, forming a drive electrode on the gate insulating film, and forming a protection element on the insulating film from a semiconductor material whose forbidden band gap is wider than silicon.

In this specification and claims, a first conductivity type and a second conductivity type are opposite to each other. In other words, if the first conductivity type is an n-type, the second conductivity type is a p-type, and if the first conductivity type is a p-type, the second conductivity type is an n-type.

### BRIEF DESCRIPTION OF THE DRAWINGS

FIG. 1 is a sectional view showing a semiconductor device according to a first embodiment of the present invention.

FIGS. 2A, 2B, 2C, 3A, 3B, 4A, and 4B are sectional views showing a method of manufacturing a semiconductor device.

FIG. 5 is a sectional view showing a semiconductor device according to a second embodiment of the present invention.

FIG. 6 is a sectional view showing a semiconductor device according to a third embodiment of the present invention.

FIG. 7 is a perspective view showing the semiconductor device of the fourth embodiment.

FIG. 8 is a sectional view showing the semiconductor device of the fourth embodiment.

FIG. 9 is a perspective view showing a semiconductor device according to a fifth embodiment of the present invention.

FIG. 10 is a perspective view showing a semiconductor device according to a sixth embodiment of the present invention.

FIG. 11 is a perspective view showing a semiconductor device according to a seventh embodiment of the present invention.

FIG. 12 is a sectional view showing a semiconductor device according to an eighth embodiment of the present invention.

FIG. 13 is a sectional view showing a semiconductor device according to a ninth embodiment of the present invention.

FIG. 14 is a sectional view showing a semiconductor device according to a modification of the ninth embodiment.

FIG. 15 is a sectional view showing a semiconductor device according to a tenth embodiment of the present invention.

FIG. 16 is a diagram showing a current-voltage characteristic between the anode electrode and the cathode electrode of the pn junction-heterojunction parallel diode 530.

FIG. 17 is a diagram showing current changes between the anode and cathode electrodes relative to ambient temperatures.

FIG. 18 is a sectional view showing a semiconductor device according to an eleventh embodiment of the present invention.

FIG. 19 shows a state in which silicon and silicon carbide are separated from each other.

FIG. 20 shows an energy band structure with silicon and silicon carbide being in contact with each other to form a heterojunction of silicon and silicon carbide.

FIG. 21 is a diagram showing the energy band gap structure of thermally balanced state with no voltage applied to the second gate electrode 319, second source electrode 322, and second drain electrode 323.

FIG. 22 is a diagram showing the energy band gap structure at the junction interface between the second source region 317 and the second drain region 316 close to the second gate electrode 319 when the second gate electrode 319 and second source electrode 322 are set at a ground potential and a given positive potential is applied to the second drain electrode 323.

FIG. 23 is a diagram showing the energy band gap structure at the junction interface between the second source region 317 and the second drain region 316 close to the second gate electrode 319 when a positive potential is applied to the second gate electrode 319.

FIG. 24 is a sectional view showing another semiconductor device according to the eighth embodiment of the present invention.

### DETAILED DESCRIPTION OF EMBODIMENTS

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified. The drawings are merely representative examples and do not limit the invention, particularly regarding such characteristics as the relationship between the thickness and width of individual layers and the ratios of the thicknesses of one layer to another. Furthermore, the invention is not limited by the relationships between and/or the ratios of the dimensions of one drawing and the dimensions of another.

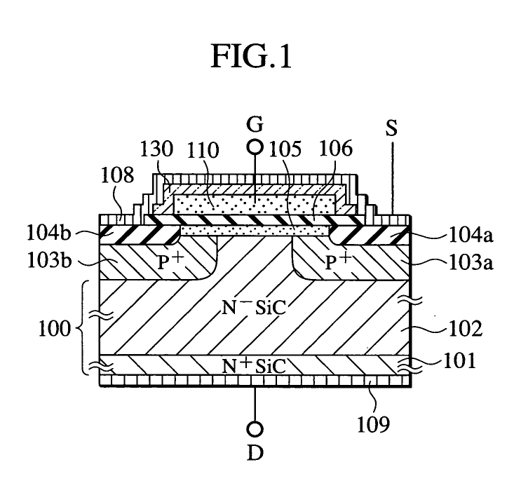

FIG. 1 is a sectional view showing a semiconductor device according to a first embodiment of the present invention. This semiconductor device has an n⁺-type substrate region 101 and an n⁻-type drain region 102 having a lower impurity concentration (dopant concentration) than the substrate region 101. The substrate region 101 and drain region 102 are formed in a silicon carbide semiconductor substrate. At the surface of the drain region 102, p⁻-type base regions 103a and 103b are formed. At the surfaces of the base regions 103a and 103b, n⁺-type source regions 104a and 104b are formed, respectively. At the surfaces of the base regions 103a and 103b, an n⁻-type surface channel region 105 is formed to connect the source regions 104a and 104b and drain region 102 to each other. On the surface channel region 105, there is formed a gate insulating film 106 on which a polysilicon carbide gate electrode 110 is formed. The gate electrode 110 is made of p⁺-type polysilicon carbide (SiC) which is a semiconductor material having a work function of 5.1 eV or over. In contact with the source regions 104a and 104b, there is formed a source electrode 108. In contact with a back face of the substrate region 101, a drain electrode 109 is formed. The gate electrode 110 is electrically insulated from the source electrode 108 with an interlayer insulating film 130. The base regions 103a and 103b are connected to the source electrode 108 at locations not depicted in FIG. 1.

Operation of the semiconductor device according to the first embodiment will be explained. First, the source electrode 108 is grounded, a positive voltage is applied to the drain electrode 109, and no voltage is applied to the polysilicon carbide gate electrode 110. The gate electrode 110 has a work function φg, the surface channel region 105 has a work function φc, and the difference between the work functions φg and φc is ,, φ1. The base regions 103a and 103b have a work function. φb and the difference between the work functions φc and φb is ,, φ2. The differences ,, φ1 and ,, φ2 form two built-in potentials that completely deplete the surface channel region 105 to establish a disconnected or nonconductive state. According to the first embodiment, the gate electrode 110 is made of p⁺-type polysilicon carbide having a work function of 5.1 eV or over, and therefore, the work function φg of the gate electrode 110 is greater than a conventional gate electrode made of p⁺-type polysilicon. As a result, it can realize a normally OFF state even if the surface channel region 105 has a high impurity concentration at which conventional semiconductor devices demonstrate a normally ON state.

Next, the source electrode 108 is grounded, a positive voltage is applied to the drain electrode 109, and a positive voltage is applied to the polysilicon carbide gate electrode 110. The surface channel region 105 under the gate insulating film 106 forms an accumulation layer. Accordingly, electrons flow from the source regions 104a and 104b through the surface channel region 105 and drain region 102 to the drain electrode 109, to establish a conductive state. As explained above, the impurity concentration of the surface channel region 105 of the semiconductor device according to the first embodiment is set higher than that of a conventional surface channel region, to realize high mobility. If the voltage applied to the gate electrode 110 is zeroed, the two built-in potentials due to ,, φ1 and ,, φ2 completely deplete the surface channel region 105 to establish a nonconductive state. In this way, the semiconductor device according to the first embodiment performs switching operation.

When a zero voltage is applied to the gate electrode 110, the source electrode 108 is grounded and a high voltage is applied to the drain electrode 109. Then, a depletion layer grows from each interface between the base regions 103a and 103b and the drain region 102. At this time, the work function φg of the gate electrode 110 and the work function φc of the surface channel region 105 have the difference ,, φ1, which forms a high-resistance layer at an interface between the gate insulating film 106 and the surface channel region 105. These depletion layers and high-resistance layer shield the gate insulating film 106 from an electric field, and therefore, the withstand voltage of the semiconductor device is not influenced by the insulation breakdown level of the gate insulating film 106. This realizes a high withstand voltage corresponding to a high insulation breakdown electric field of silicon carbide.

As explained above, the semiconductor device according to the first embodiment has the source regions 104a and 104b and drain region 102 of a first conductivity type (n-type in this embodiment) formed at predetermined locations, the surface channel region 105 formed on the source regions 104a and 104b and drain region 102, the gate insulating film 106, and the gate electrode 110 formed on the gate insulating film 106 adjacent to the surface channel region 105. The gate electrode 110 is made of a semiconductor material having a work function of 5.1 eV or over. This configuration realizes a normally OFF state, high mobility, and high withstand voltage.

In more detail, the semiconductor device according to the first embodiment has the semiconductor substrate region 101 of the first conductivity type (n-type in this embodiment), the epitaxial layer 102 of the first conductivity type formed on a first principal plane of the semiconductor substrate region 101 and having a lower impurity concentration than the semiconductor substrate region 101, the base regions 103a and 103b of a second conductivity type (p-type in this embodiment) formed in predetermined areas at the surface of the epitaxial layer 102 and having a predetermined depth, the source regions 104a and 104b of the first conductivity type formed in predetermined areas at the surfaces of the base regions 103a and 103b, respectively, and being shallower than the base regions 103a and 103b, the surface channel region 105 formed to connect the source regions 104a and 104b and epitaxial layer 102 to each other, the gate insulating film 106, the gate electrode 110 formed on the gate insulating film 106 adjacent to the surface channel region 105 from a semiconductor material having a work function of 5.1 eV or over, the source electrode 108 formed in contact with the base regions 103a and 103b and source regions 104a and 104b (the base regions 103a and 103b and source electrode 108 being in contact with each other at locations not shown in FIG. 1), and the drain electrode 109. This configuration realizes a normally OFF state, high mobility, and high withstand voltage.

The surface channel region 105 is of the first conductivity type, to realize a normally OFF state and high mobility. The semiconductor material having a work function of 5.1 eV or over is of the second conductivity type, to secure the normally OFF state. The semiconductor material having a work function of 5.1 eV or over may be silicon carbide to improve an OFF characteristic of the accumulation layer (+1.5 V). Accordingly, the accumulation layer may have a high impurity concentration to reduce ON resistance. Such a semiconductor material shows no normally ON state under the operational environment such as a high-temperature treatment of about 300° C., and therefore, is adoptable to easily establish a normally OFF state. The gate electrode 110 can easily be processed by doping and etching. The semiconductor substrate region 101 and epitaxial layer 102 are made of silicon carbide to realize a high withstand voltage. The embodiment particularly employs the silicon carbide epitaxial layer.

According to the first embodiment, the surface channel region 105 is of an accumulation type. Instead, it may be of an inversion type. Even if it is of the inversion type, the same electric field shielding effect is provided. In this case, the work function φg of the p⁺-type polysilicon carbide gate electrode 110 and the work function φe of the silicon carbide epitaxial layer 102 provide a difference ,, φ1′ that forms a high-resistance layer at an interface between the gate insulating film 106 and the epitaxial layer 102. The semiconductor device according to the first embodiment is also usable in a reversely conductivity state.

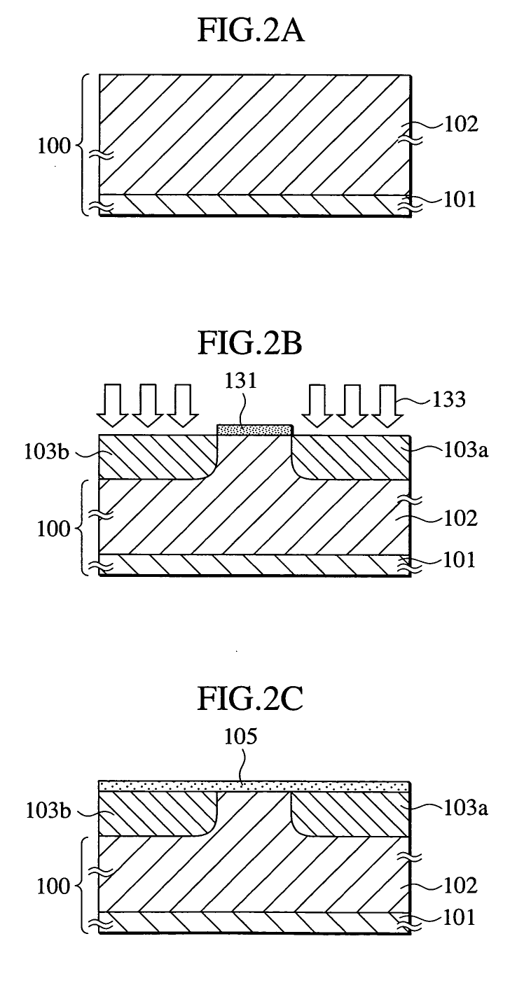

A method of manufacturing the semiconductor device according to the first embodiment of the present invention will be explained with reference to FIGS. 2A to 4B. In FIG. 2A, a silicon carbide semiconductor base is prepared from an n⁺-type silicon carbide substrate 101 and an n⁻-type drain region 102 formed on the substrate 101. The silicon carbide epitaxial layer 102 has an impurity concentration of, for example, 1×10¹⁶ cm⁻³ and a thickness of, for example, 10 ,,m.

In FIG. 2B, an LTO (low temperature oxide) film 131 is deposited on the drain region 102 by CVD, and the LTO film 131 is patterned by photolithography and etching. The patterned LTO film 131 is used as a mask to implant aluminum (Al) ions 133 that form base regions 103a and 103b in predetermined areas of the silicon carbide epitaxial layer 102. The Al-ion implantation is carried out under the conditions of, for example, 360 keV in acceleration energy, 5×10¹³ cm⁻² in dose quantity, and 800° C. in substrate temperature.

In FIG. 2C, the LTO film 131 is removed with buffered hydrofluoric acid solution. The n⁻-type drain region 102 is epitaxially grown to 0.2 ,,m thick by CVD, to form a surface channel region 105. The epitaxial growth is carried out under the conditions of, for example, SiH₄ (monosilane) and C₃H₈ (propane) as material gas, H₂ as carrier gas, N₂ as dopant gas, 1600° C. in substrate temperature, 0.5 in carbon (C) to silicon (Si) ratio, and 2×10¹⁷ cm⁻³ in nitrogen (N) concentration in the silicon carbide epitaxial layer 102.

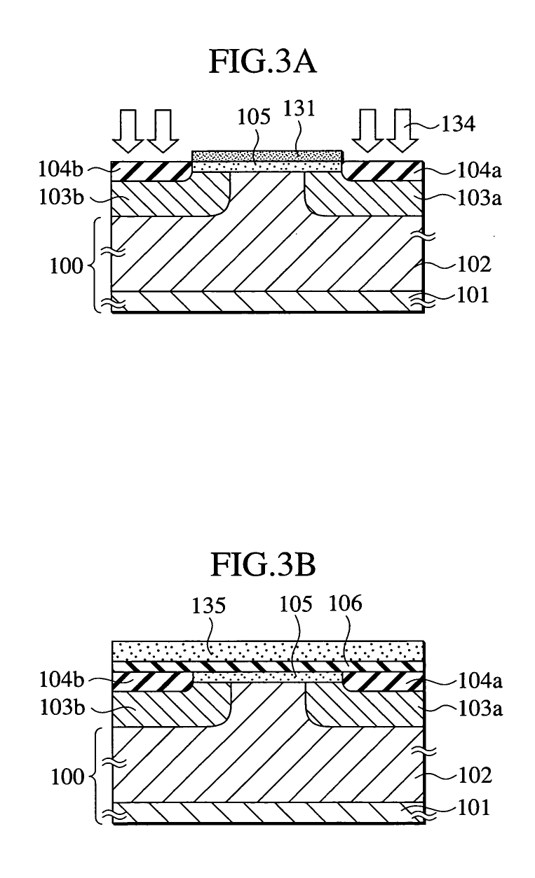

In FIG. 3A, an LTO film 131 is deposited on the drain region 102 by CVD and is patterned by photolithography and etching. The patterned LTO film 131 is used as a mask to implant phosphorus (P) ions 134 that form source regions 104a and 104b in predetermined areas of the base regions 103a and 103b. The P-ion implantation is carried out under the conditions of, for example, 30 to 100 keV in acceleration energy, 3×10¹⁵ cm⁻² in total dose quantity, and 800° C. in substrate temperature. This ion implantation is carried out in multiple (three) stages. The LTO film 131 is removed with buffered hydrofluoric acid solution. An activation heat treatment to activate the implanted Al and P ions is carried out under the conditions of, for example, argon (Ar) as an atmosphere, 1600° C. in temperature, and 20 minutes in time.

In FIG. 3B, a thermal oxidation film serving as a gate insulating film 106 is formed to a thickness of, for example, 500 angstroms. On the gate insulating film 106, a p⁺-type polysilicon carbide layer 135 serving as a gate electrode is formed to a thickness of, for example, 3500 angstroms by PLD (pulse laser deposition) at a substrate temperature of 950° C.

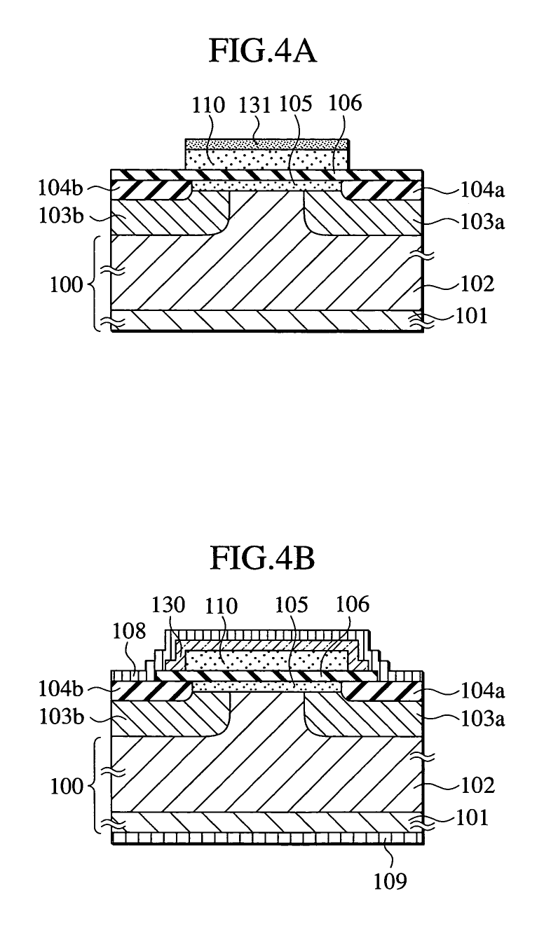

In FIG. 4A, an LTO film 131 is deposited on the polysilicon carbide layer 135 by CVD and is patterned by photolithography and etching to form a mask. The polysilicon carbide layer 135 is patterned by reactive ion etching to form a p⁺-type polysilicon carbide gate electrode 110.

In FIG. 4B, the LTO film 131 is removed with buffered hydrofluoric acid solution. An interlayer insulating film 130 is deposited, a contact hole is formed in a predetermined part, nickel (Ni) is deposited, and a source electrode 108 is formed. Ni is deposited on a back face of the silicon carbide substrate 101, to form a drain electrode 109. Contact annealing is carried out to complete the semiconductor device of the first embodiment shown in FIG. 1. The contact annealing is carried out, for example, in an Ar atmosphere at 1000° C. for two minutes.

(Second Embodiment)

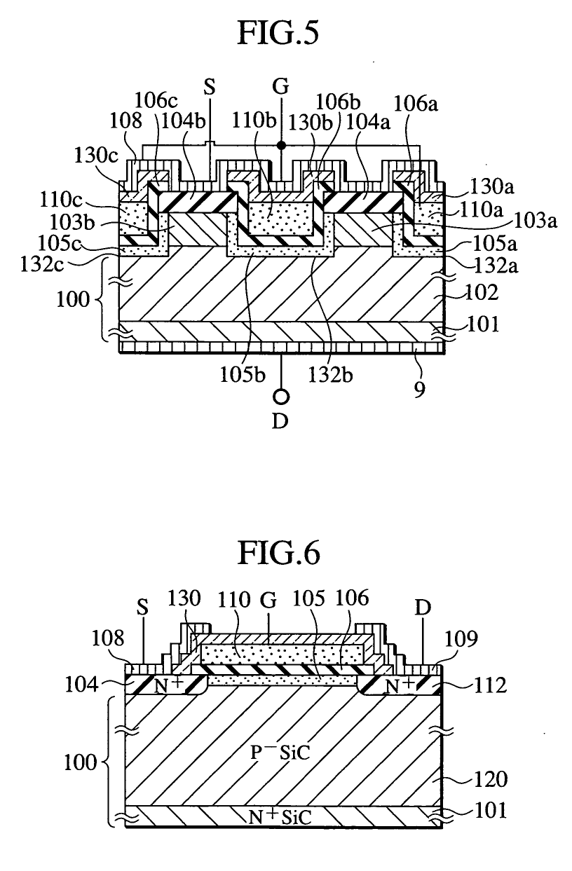

FIG. 5 is a sectional view showing a semiconductor device according to a second embodiment of the present invention. The semiconductor device has an n⁺-type substrate region 101 and an n⁻-type drain region 102 formed on the substrate region 101. The drain region 102 has a lower impurity concentration than the substrate region 101. At the surface of the drain region 102, p⁻-type base regions 103a and 103b are formed. At predetermined locations on the surfaces of the base regions 103a and 103b, trenches 132a, 132b, and 132c are formed through the base regions 103a and 103b up to the drain region 102. At predetermined locations on the surfaces of the base regions 103a and 103b, n⁺-type source regions 104a and 104b are formed. On the inner side walls of the trenches 132a, 132b, and 132c and on the base regions 103a and 103b, n⁻-type surface channel regions 105a, 105b, and 105c are formed to connect the source regions 104a and 104b to the drain region 102. On the surface channel regions 105a, 105b, and 105c, gate insulating films 106a, 106b, and 106c are formed. On the gate insulating films, gate electrodes 110a, 110b, and 110c are formed from p⁺-type polysilicon carbide which is a semiconductor material having a work function of 5.1 eV or over. In contact with the source regions 104a and 104b, a source electrode 108 is formed. On a back face of the substrate region 101, a drain electrode 109 is formed. The gate electrodes 110a, 110b, and 110c are electrically insulated from the source electrode 108 with interlayer insulating films 130a, 130b, and 130c. The base regions 103a and 103b are connected to the source electrode 108 at locations not shown in FIG. 5.

In addition to the operation and effect of the semiconductor device of the first embodiment, the semiconductor device of the second embodiment is capable of minimizing the device, i.e., integrating elements because the surface channel regions 105a, 105b, and 105c are formed on the inner side walls of the trenches 132a, 132b, and 132c. The second embodiment is capable of realizing lower ON resistance than the first embodiment. As mentioned above, the semiconductor device according to the second embodiment has the semiconductor substrate 101 of a first conductivity type, the epitaxial layer 102 of the first conductivity type formed on a first principal plane of the semiconductor substrate 101 and having a lower impurity concentration than the semiconductor substrate 101, the base regions 103a and 103b of a second conductivity type formed on a principal plane of the epitaxial layer 102, the trenches 132a, 132b, and 132c formed adjacent to the base regions 103a and 103b and extended up to the epitaxial layer 102, the source regions 104a and 104b of the first conductivity type formed in predetermined areas at the surfaces of the base regions 103a and 103b and being shallower than the base regions 103a and 103b, the surface channel regions 105a, 105b, and 105c formed on the inner side walls of the trenches 132a, 132b, and 132c to connect the source regions 104a and 104b to the epitaxial layer 102, the gate insulating films 106a, 106b, and 106c, the gate electrodes 110a, 110b, and 110c formed on the gate insulating films adjacent to the surface channel regions 105a, 105b, and 105c from a semiconductor material having a work function of 5.1 eV or over, the source electrode 108 formed in contact with the base regions 103a and 103b and source regions 104a and 104b, and the drain electrode 109 formed at a predetermined location. This configuration realizes a normally OFF state, high mobility, high withstand voltage, and low ON resistance.

(Third Embodiment)

FIG. 6 is a sectional view showing a semiconductor device according to a third embodiment of the present invention. The semiconductor device has an n⁺-type substrate region 101 and a p⁻type epitaxial layer 120 formed on the substrate region 101. The epitaxial layer 120 has a lower impurity concentration than the substrate region 101. At predetermined locations on the surface of the epitaxial layer 120, an n⁺-type source region 104 and an n⁺-type drain region 112 are formed. On the surface of the epitaxial layer 120, there is formed an n⁻-type surface channel region 105 to connect the source region 104 to the drain region 112. On the surface channel region 105, a gate insulating film 106 is formed, and on the gate insulating film 106, a gate electrode 110 is formed from a p⁺-type polysilicon carbide which is a semiconductor material having a work function of 5.1 eV or over. In contact with the source region 104, a source electrode 108 is formed. In contact with the drain region 112, a drain electrode 109 is formed. (The drain electrode 109 is formed in contact with a back face of the substrate region 101.) The gate electrode 110, source electrode 108, and drain electrode 109 are electrically insulated from one another with an interlayer insulating film 130. The epitaxial layer 120 and source electrode 108 are connected to each other at a location not shown in FIG. 6.

In this way, the semiconductor device according to the third embodiment has the semiconductor substrate 101, the epitaxial layer 120 of a second conductivity type formed on a first principal plane of the semiconductor substrate 101 and having a lower impurity concentration than the semiconductor device 101, the source region 104 and drain region 112 of a first conductivity type formed in predetermined areas of a first surface of the epitaxial layer 120 and shallower than the epitaxial layer 120, the surface channel region 105 formed to connect the source region 104 and drain region 112 to each other, the gate insulating film 106, the gate electrode 110 formed on the gate insulating film 106 adjacent to the surface channel region 105 from a semiconductor material having a work function of 5.1 eV or over, the source electrode 108 formed in contact with the source region 104, and the drain electrode 109 formed in contact with the drain region 112. This configuration realizes a normally OFF state and high mobility.

The semiconductor devices according to the first and second embodiments are a vertical planar power MOSFET and a trench power MOSFET, respectively. The present invention is not limited to these power MOSFETs. The present invention is also applicable to horizontal power MOSFETs such as the one explained with reference to the third embodiment. Namely, the present invention is applicable to any semiconductor device that forms a gate electrode adjacent to a surface channel region through a gate insulating film, to realize high mobility and a normally OFF state. The substrate region 101 of any one of the first to third embodiments may be made of silicon carbide.

Although the embodiments employ polysilicon carbide as a gate electrode material, it is possible to employ any semiconductor material such as gallium nitride (GaN), gallium arsenide (GaAs), or diamond if the material has a work function of 5.1 eV or over.

The above-mentioned embodiments employ silicon carbide substrates. Instead, the present invention can employ other semiconductor substrates such as silicon substrates, to realize the same effect.

In the above-mentioned embodiments, the first conductivity type is “n” and the second conductivity type “p.” Instead, the first conductivity type may be “p” and the second conductivity type “n.”

(Fourth Embodiment)

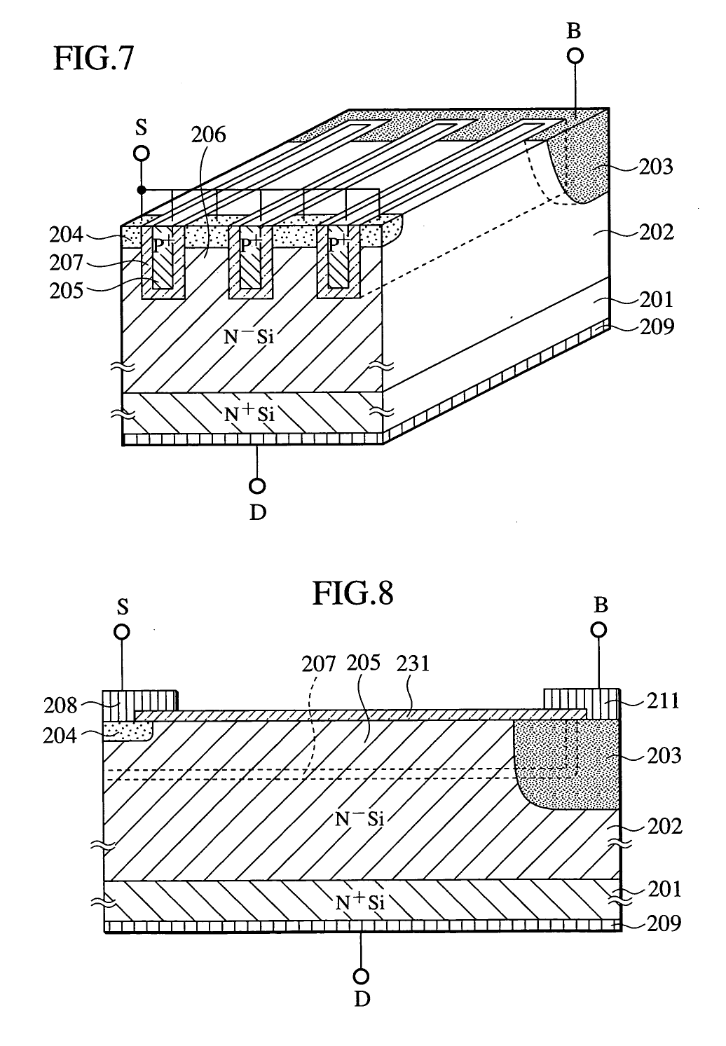

FIGS. 7 and 8 show a semiconductor device according to a fourth embodiment of the present invention. This semiconductor device employs a silicon substrate.

FIG. 7 is a perspective view showing the semiconductor device of the fourth embodiment and FIG. 8 is a sectional view showing the same. For the sake of clear explanation, FIG. 7 strips off a metal film serving as a surface electrode and a surface protection film. It is naturally possible to employ these metal film electrode and surface protection film. The semiconductor device has an n⁺-type substrate region 201, an n-type drain region 202, an n⁺-type source region 204, an insulating film 207, an insulated electrode 205, and a p-type base region 203. The insulating film 207 and insulated electrode 205 are formed in a U-shape in a trench having substantially vertical side walls. The insulated electrode 205 is insulated from the drain region 202 by the insulating film 207. In FIG. 7, the source region 204 is in contact with the insulating film 207. The source region 204 may not be in contact with the insulating film 207 if the source region 204 is sandwiched between the insulated electrodes 205. A part of the drain region 202 between the adjacent insulated electrodes 205 with the insulating films 207 interposed between them serves as a channel region 206.

According to this embodiment, the insulated electrode 205 is made of, instead of high-concentration p⁺-type polysilicon, high-concentration p⁺-type silicon carbide (SiC), for example, because SiC increases a built-in potential difference between the insulated electrode 205 and the adjacent drain region 202 and spreads a depletion layer into the drain region 202.

A drain electrode 209 forms an ohmic contact with the substrate region 201. A source electrode 208 (shown in FIG. 8) forms an ohmic contact with the source region 204 and insulated electrode 205 through a contact hole formed in an interlayer insulating film 231 (shown in FIG. 8). A base electrode 211 forms an ohmic contact with the base region 203 through a contact hole formed in the interlayer insulating film 231.

Operation of the semiconductor device according to the fourth embodiment will be explained. This embodiment has bidirectional conduction characteristics enabling a forward operation and a reverse operation. In the forward operation, the source electrode 208 is grounded, a positive potential is applied to the drain electrode 209, and a control signal is applied to the base electrode 211. In the reverse operation, the drain electrode 209 is grounded and a positive potential is applied to the source electrode 208 and base electrode 211.

First, the forward operation will be explained. For example, the source electrode 208 is grounded, a proper positive potential is applied to the drain electrode 209 through, for example, inductive load (L-load), and the base electrode 211 is grounded. Then, the semiconductor device maintains a nonconductive or disconnected state. Namely, around the insulated electrode 205, a built-in depletion layer is formed due to a work function difference between the insulated electrode 205 and the channel region 206. According to the embodiment, a work function difference between p-type silicon carbide and n-type silicon is greater than a conventional one between p-type silicon and n-type silicon. As a result, the depletion layer of the embodiment is stronger. If the distance between the adjacent two insulated electrodes 205 on each side of the insulating films 207 in the channel region 206 is equal to that of the conventional structure, the embodiment can further reduce a leakage current between the drain electrode 209 and the source electrode 208, to further improve disconnecting performance.

Next, a positive potential of, for example, +0.5 V is applied to the base electrode 211. Then, positive holes flow from the p-type base region 203 applied with the positive potential to an interface of the insulating film 207, to form an inversion layer. This blocks electric force lines from the insulated electrode 205 to the channel region 206 forming a potential barrier, resulting in lowering the potential barrier in the channel region 206 against conductive electrons. As a result, the drain region 202 and source region 204 become conductive. When the potential to the base electrode 211 is further increased, a pn junction between the p-type base region 203 and the n-type peripheral region is forwardly biased, and positive holes are directly injected into the drain region 202 and channel region 206. This increases the conductivity of the n-type region that is provided with a low impurity concentration to realize high resistance and secure an element withstand voltage. Then, a flow of electrons forming a drain current passes from the source region 204 to the substrate region 201 with low resistance. Namely, the semiconductor device of this embodiment demonstrates performance equivalent to a conventional device.

To turn off the semiconductor device, a ground potential (0 V) or a negative potential is applied to the base electrode 211. Then, excessive positive holes in the drain region 202 and channel region 206 flow into the base region 203, and the concentration of positive holes gradually decreases from around the base region 203. Excessive positive holes in the drain region 202 far from the base region 203 move toward the low-potential surface channel region 206. In this way, the positive holes in the drain region 202 are speedily depleted through the low-resistance inversion layer, and therefore, the semiconductor device is turned off at high speed.

Next, the reverse operation will be explained. For example, the drain electrode 209 is grounded, a proper positive potential is applied to the source electrode 208 through, for example, inductive load (L-load), and a positive potential of, for example, +0.7 V or higher is applied to the base electrode 211. This establishes a reversely conducted state for the element formed in an active region of the substrate region 201. Like the forward operation, the reverse operation flows positive holes from the p-type base region 203 to the interface of the insulating film 207 to form an inversion layer. This blocks electric force lines from the insulated electrode 205 to the channel region 206 forming a potential barrier, resulting in lowering the potential barrier in the channel region 206 against conductive electrons. As a result, the drain region 202 and source region 204 become conductive. The pn junction between the p-type base region 203 and the n-type peripheral region is forwardly biased, and positive holes are directly injected into the drain region 202 and channel region 206. Then, a flow of electrons passes from the substrate region 201 to the source region 204 with low resistance. In the reversely conductive state, a pn diode between the p-type base region 203 and the n-type drain region 202 turns on to pass a current between the base region 203 and the drain region 202. Next, a ground potential (0 V) or a negative potential is applied to the source region 204 and base region 203 to shift the conductive state to a nonconductive state. Excessive positive holes in the drain region 202 flow into the base region 203 and they are discharged to the base electrode 211. In this way, the reverse operation shows performance equivalent to the conventional structure.

As explained above, the semiconductor device according to the fourth embodiment has the n⁺-type substrate region 201 forming a drain region of a first conductivity type (n-type in this embodiment), parallel trenches formed in a principal plane of the n-type drain region 202, the source region 204 of the first conductivity type formed in contact with parts of the principal plane between the trenches, the base region 203 of a second conductivity type (p-type in this embodiment) formed in contact with the parts of the principal plane and separated from the source region 204, the insulating film 207 formed in the trench, and the insulated gate 205 formed in the trench, insulated from the drain region 202 with the insulating film 207, and having the same potential as the source region 204. The insulated electrode 205 is made of a semiconductor material that increases a built-in potential difference at least between the insulated electrode 205 and the channel region 206 in the drain region 202 between the adjacent insulated electrodes 205 to grow a depletion layer into the drain region 202, compared with polysilicon of the second conductivity type having as high impurity concentration as possible. Instead of polysilicon of the second conductivity type having as high impurity concentration as possible, the fourth embodiment employs, to form the insulated electrode 205, the semiconductor material that is capable of increasing the built-in potential difference between the insulated electrode 205 and the drain region 202 between the adjacent insulated electrodes 205 and growing a depletion layer into the drain region 202. If the distance between the adjacent two insulated electrodes 205 facing each other with the insulating films 207 interposed between them is equal to that of the conventional structure, the embodiment can form a higher potential barrier to improve cutoff performance.

The semiconductor material according to the embodiment is of the second conductivity type, to further increase: a potential barrier against conductive electrons, to thereby improve cutoff performance.

The semiconductor material according to the embodiment may be silicon carbide to make the production of the semiconductor device easier.

(Fifth Embodiment)

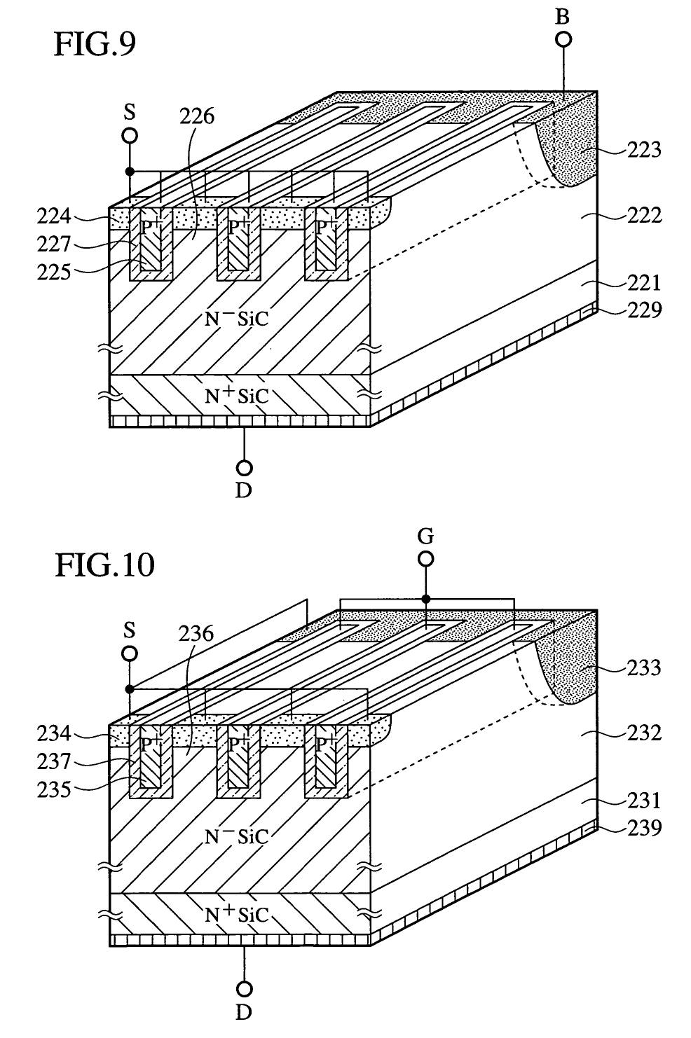

FIG. 9 is a perspective view showing a semiconductor device according to a fifth embodiment of the present invention and corresponds to FIG. 7. In this embodiment, the semiconductor device employs silicon carbide as a substrate material. For the clarity of explanation, FIG. 9 omits a metal film serving as a surface electrode and a surface protection film. This semiconductor device has an n⁺-type substrate region 221, an n-type drain region 222, an n⁺-type source region 224, an insulating film 227, an insulated electrode 225, and a p-type base region 223. The insulating film 227 and insulated electrode 225 are formed in a U-shape in a trench having substantially vertical side walls according to this embodiment. The insulated electrode 225 is insulated from the drain region 222 by the insulating film 227. In FIG. 9, the source region 224 is in contact with the insulating film 227. The source region 224 may not be in contact with the insulating film 227 if the source region 224 is sandwiched between the insulated electrodes 225. A part of the drain region 222 between the adjacent insulated electrodes 225 with the insulating films 227 interposed between them serves as a channel region 226.

The semiconductor device of this embodiment is characterized in that it employs a silicon carbide substrate. Namely, the substrate region 221, drain region 222, source region 224, channel region 226, and base region 223 are made of silicon carbide. Like the fourth embodiment, the insulated electrode 225 of the fifth embodiment is made of a semiconductor material such as high-concentration p⁺-type silicon carbide, instead of p⁺-type polysilicon, to increase a built-in potential difference between the insulated electrode 225 and the drain region 222 between the adjacent insulated electrodes 225 and extend a depletion layer into the drain region 222. Like the fourth embodiment, the fifth embodiment forms an ohmic contact between a drain electrode 229 and the substrate region 221, between a source electrode (not shown) and the source region 224 and insulated electrode 225, and between a base electrode (not shown) and the base region 223.

Operation of the fifth embodiment will be explained. Like the fourth embodiment, the fifth embodiment has bidirectional conduction characteristics enabling forward and reverse operations. Operation of the fifth embodiment that is different from the fourth embodiment will be explained. For example, the source electrode is grounded, a proper positive potential is applied to the drain electrode 229 through inductive load (L-load), and the base electrode is grounded. Then, the semiconductor device maintains a disconnected or nonconductive state. Around the insulated electrode 225, a built-in depletion layer is formed due to a work function difference between the insulated electrode 225 and the channel region 226. A work function difference between p-type silicon carbide and n-type silicon of the fifth embodiment is greater than a work function difference between p-type silicon carbide and n-type silicon of the fourth embodiment, and therefore, the fifth embodiment can grow a stronger depletion layer. If the distance between the adjacent two insulated electrodes 225 facing each other with the insulating films 227 interposed between them is equal to that of the fourth embodiment, the fifth embodiment can further reduce a leakage current between the drain electrode 229 and the source electrode and improve cutoff performance. The fifth embodiment employs a semiconductor substrate made of silicon carbide, and therefore, is usable at high temperatures over, for example, 200° C. Namely, the fifth embodiment demonstrates improved cutoff performance at high temperatures.

When a positive potential of, for example, +0.5 V is applied to the base electrode, positive holes flow from the p-type base region 223 applied with the positive potential to an interface of the insulating film 227, to form an inversion layer. This blocks electric force lines from the insulated electrode 225 to the channel region 226 forming a potential barrier, resulting in lowering the potential barrier in the channel region 226 against conductive electrons. As a result, the drain region 222 and source region 224 become conductive. When the potential to the base electrode is further increased, a pn junction between the p-type base region 223 and the n-type peripheral region is forwardly biased, and positive holes are directly injected into the drain region 222 and channel region 226. This increases the conductivity of the n-type region that is provided with a low impurity concentration to realize high resistance and secure an element withstand voltage. At this time, a flow of electrons forming a drain current passes from the source region 224 to the substrate region 221 with low resistance. The fifth embodiment employs a substrate made of silicon carbide whose avalanche breakdown electric field is greater than that of silicon by about one digit, and therefore, the drain region 222 may be thinner than that of the fourth embodiment to realize an equivalent withstand voltage. Namely, the volume of the drain region 222 whose conductivity must be increased by introducing positive holes can be smaller than that of the fourth embodiment. This means that the fifth embodiment can reduce the quantity of positive holes injected from the base region 223, i.e., a base driving current, thereby simplifying a base driving circuit.

To turn off the semiconductor device, a ground potential (0 V) or a negative potential is applied to the base electrode. Then, excessive positive holes in the drain region 222 and channel region 226 flow into the base region 223, and the concentration of positive holes gradually decreases from around the base region 223. Excessive positive holes in the drain region 222 far from the base region 223 move toward the low-potential surface channel region 226. In this way, positive holes in the drain region 222 are speedily depleted through the low-resistance inversion layer. According to the fifth embodiment, the quantity of positive holes injected into the drain region 222 under a conductive state is originally small, and therefore, the fifth embodiment can establish a nonconductive state speedier than the fourth embodiment.

(Sixth Embodiment)

FIG. 10 is a perspective view showing a semiconductor device according to a sixth embodiment of the present invention and corresponds to FIG. 7. In this embodiment, the semiconductor device employs silicon carbide as a substrate material. For the clarity of explanation, FIG. 10 omits a metal film serving as a surface electrode and a surface protection film. This semiconductor device has an n⁺-type substrate region 231, an n-type drain region 232, an n⁺-type source region 234, an insulating film 237, an insulated electrode 235, and a p-type base region 233. The insulating film 237 and insulated electrode 235 are formed in a U-shape in a trench having substantially vertical side walls. The insulated electrode 235 is insulated from the drain region 232 by the insulating film 237. In FIG. 10, the source region 234 is in contact with the insulating film 237. The source region 234 may not be in contact with the insulating film 237 if the source region 234 is sandwiched between the insulated electrodes 235. A part of the drain region 232 between the adjacent insulated electrodes 235 with the insulating films 237 interposed between them serves as a channel region 236. The insulated electrode 235 is made of a semiconductor material such as high-concentration p⁺-type silicon carbide, instead of p⁺-type polysilicon, to increase a built-in potential difference between the insulated electrode 235 and the drain region 232 between the adjacent insulated electrodes 235 and spread a depletion layer into the drain region 232. The insulated electrode 235 is connected to a gate electrode (not shown).

A drain electrode 239 and the substrate region 231 form an ohmic contact, and a source electrode (not shown) and the source region 234 and base region 233 form an ohmic contact.

Operation of the sixth embodiment will be explained. According to this embodiment, the source electrode is grounded, a positive potential is applied to the drain electrode 239, and a control signal is applied to the gate electrode, to carry out a forward operation. The drain electrode 239 is grounded, a positive potential is applied to the source electrode, and a control signal is applied to the gate electrode, to conduct a reverse operation. In this way, the sixth embodiment has bidirectional conduction characteristics.

First, the forward operation will be explained. For example, the source electrode is grounded, a proper positive potential is applied to the drain electrode 239 through, for example, inductive load (L-load), and the base electrode is grounded. Then, the semiconductor device maintains a nonconductive or disconnected state. Namely, around the insulated electrode 235, a built-in depletion layer is formed due to a work function difference between the insulated electrode 235 and the channel region 236. According to the embodiment, a work function difference between p-type silicon carbide and n-type silicon carbide is greater than a conventional one between p-type silicon and n-type silicon. As a result, the depletion layer of the embodiment is stronger than a conventional one. If the distance between the adjacent two insulated electrodes 235 on each side of the insulating films 237 in the channel region 236 is equal to that of the conventional structure, the embodiment can further reduce a leakage current between the drain electrode 239 and the source electrode, to further improve disconnecting performance.

Next, a positive potential of, for example, +0.5 V is applied to the gate electrode. Then, the built-in depletion layer spread in the channel region 236 retracts to lower a potential barrier in the channel region 236 against conductive electrons and make the drain region 232 and source region 234 conductive. To turn off the semiconductor device, a ground potential (0 V) or a negative potential is applied to the base electrode. Then, a built-in depletion layer again grows into the channel region 236 to disconnect the element at high speed.

In this way, the sixth embodiment actively applies a drive potential to the insulated electrode 235, to actively change the potential of the channel region 236. Accordingly, this embodiment is applicable to a wide range of usages such as high-speed switches. As mentioned above, the semiconductor device according to the sixth embodiment has a semiconductor substrate of a first conductivity type serving as a drain region 232, parallel trenches formed on a principal plane of the semiconductor substrate, a source region 234 of the first conductivity type formed in contact with parts of the principal plane between the trenches, an insulating film 237 formed in the trench, and an insulated electrode 235 formed in the trench and insulated from the drain region 232 by the insulating film 237. Instead of polysilicon of the second conductivity type having as high impurity concentration as possible, a semiconductor material that increases a built-in potential difference between the insulated electrode 235 and the drain region 232 between the adjacent insulated electrodes 235 and grows a depletion layer into the drain region 232 is employed to form the insulated electrode 235. If the distance between the adjacent two insulated electrodes (gate electrodes) 235 facing each other with the insulating films 237 interposed between them is equal to that of the conventional structure, the embodiment can form a higher potential barrier against conductive electrons to improve cutoff performance. This embodiment forms the base region of the second conductivity type in contact with the principal plane between the trenches and keeps the potential of the base region at the potential of one of the source region and insulated gate. This configuration drains positive holes generated in the drain region to the base electrode through the base region, to further improve the cutoff performance.

(Seventh Embodiment)

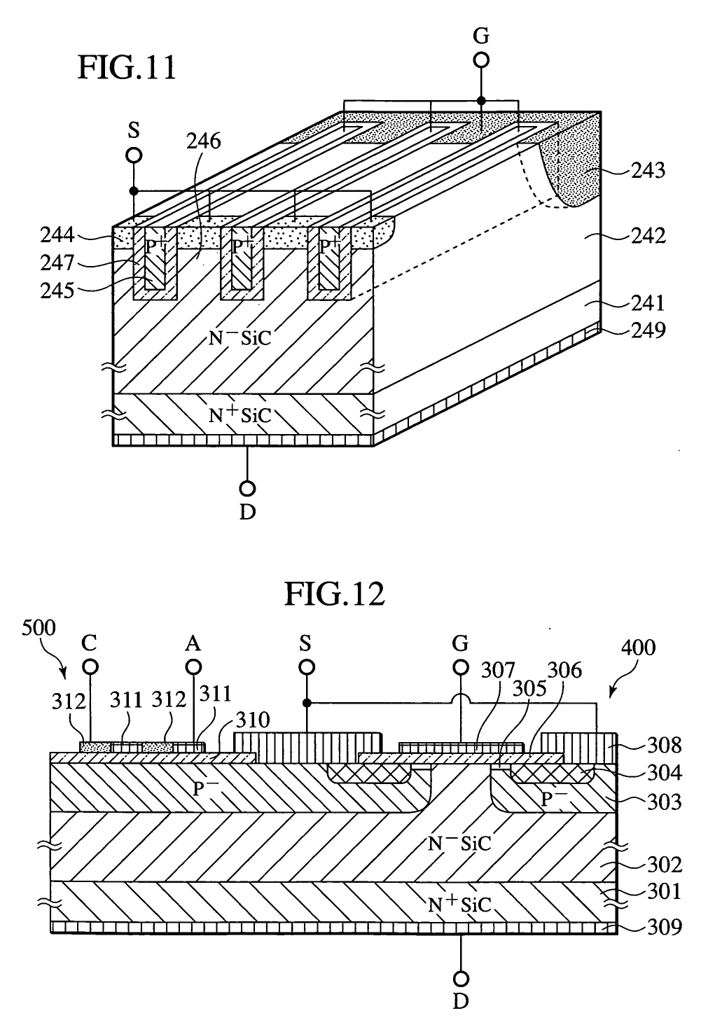

FIG. 11 is a perspective view showing a semiconductor device according to a seventh embodiment of the present invention and corresponds to FIG. 7. In this embodiment, the semiconductor device employs silicon carbide as a substrate material. For the clarity of explanation, FIG. 11 omits a metal film serving as a surface electrode and a surface protection film. This semiconductor device has an n⁺-type substrate region 241, an n-type drain region 242, an n⁺-type source region 244, an insulating film 247, an insulated electrode 245, and a p-type base region 243. The insulating film 247 and insulated electrode 245 are formed in a U-shape in a trench having substantially vertical side walls. The insulated electrode 245 is insulated from the drain region 242 by the insulating film 247. In FIG. 11, the source region 244 is in contact with the insulating film 247. The source region 244 may not be in contact with the insulating film 247 if the source region 244 is sandwiched between the insulated electrodes 245. A part of the drain region 242 between the adjacent insulated electrodes 245 with the insulating films 247 interposed between them forms a channel region 246.

According to this embodiment, the insulated electrode 245 is made of a semiconductor material such as high-concentration p⁺-type silicon carbide, instead of p⁺-type polysilicon, to increase a built-in potential difference between the insulated electrode 245 and the drain region 242 between the adjacent insulated electrodes 245 and spread a depletion layer into the drain region 242. The insulated electrode 245 and base electrode 243 are connected to a gate electrode (not shown). A drain electrode 249 and the substrate region 241 form an ohmic contact, and a source electrode (not shown) and the source region 244 form an ohmic contact.

Operation of the seventh embodiment will be explained. According to this embodiment, the source electrode is grounded, a positive potential is applied to the drain electrode 249, and a control signal is applied to the gate electrode, to carry out a forward operation. The drain electrode 249 is grounded, a positive potential is applied to the source electrode, and a control signal is applied to the gate electrode, to conduct a reverse operation. In this way, the seventh embodiment has bidirectional conduction characteristics.

First, the forward operation will be explained. For example, the source electrode is grounded, a proper positive potential is applied to the drain electrode 249 through, for example, inductive load (L-load), and the gate electrode is grounded. Then, the semiconductor device maintains a nonconductive state. Namely, around the insulated electrode 245, a built-in depletion layer is formed due to a work function difference between the insulated electrode 245 and the channel region 246. According to the embodiment, a work function difference between p-type silicon carbide and n-type silicon carbide is greater than a conventional one between p-type silicon and n-type silicon. As a result, the depletion layer of the embodiment is stronger than a conventional one. If the distance between the adjacent two insulated electrodes 245 on each side of the insulating films 247 in the channel region 246 is equal to that of the conventional structure, the embodiment can further reduce a leakage current between the drain electrode 249 and the source electrode, to further improve disconnecting performance.

Next, a positive potential of, for example, +0.5 V is applied to the gate electrode. Then, the built-in depletion layer spread in the channel region 246 retracts to lower a potential barrier in the channel region 246 against conductive electrons and make the drain region 242 and source region 244 conductive. When the potential of the gate electrode is further decreased, a pn junction between the p-type base region 243 and the n-type peripheral region is forwardly biased to directly inject positive holes into the drain region 242 and channel region 246. This increases the conductivity of the n-type region that is provided with a low impurity concentration to realize high resistance. Then, a flow of electrons in the drain region passes from the source region 244 to the substrate region 241 with low resistance. To turn off the semiconductor device, a ground potential (0 V) or a negative potential is applied to the base electrode. Then, a built-in depletion layer again grows into the channel region 246 to disconnect the element at high speed.

In this way, the seventh embodiment actively applies a drive potential to the insulated electrode 245, to actively change the potential of the channel region 246. In addition, the embodiment injects positive holes into the drain region 242 to decrease resistance, and therefore, is widely applicable as a switch of high cutoff performance and low ON resistance.

According to the fourth embodiment, the semiconductor device employs a silicon substrate. According to the fifth to seventh embodiments, each semiconductor device employs a silicon carbide substrate. Instead, the substrate may be made of any other semiconductor material such as silicon germanium, gallium nitride, gallium arsenide, or diamond. The silicon carbide may have an optional polytype such as 4H, 6H, and 3C. According to the embodiments, a drain electrode and a source electrode face each other with a drain region interposed between them, and a drain current vertically flows to form a vertical transistor. Instead, the drain electrode and source electrode may be arranged on the same principal plane to horizontally pass a drain current and form a horizontal transistor. According to the embodiments, drain and source regions have a conductivity type of “n” and majority carriers are electrons. Instead, the drain and source regions may have a conductivity type of “p” and majority carriers are positive holes. The embodiments form insulated electrodes from silicon carbide. Instead, the insulated electrodes may be made of any semiconductor material such as gallium nitride, gallium arsenide, and diamond that can increase a built-in potential difference between the insulated electrode and the drain region between the adjacent insulated electrodes and can expand a depletion layer into the drain region compared with high-concentration p⁺-type polysilicon. In this way, any one of the fourth to seventh embodiments can provide a semiconductor device structure capable of improving cutoff performance at the same processing accuracy as the related art.

(Eighth Embodiment)

FIG. 12 is a sectional view showing a semiconductor device according to an eighth embodiment of the present invention. This embodiment employs a substrate made of silicon carbide which is semiconductor having a wider forbidden band gap than silicon.

In FIG. 12, the semiconductor device has a semiconductor substrate made of silicon carbide having a polytype of, for example, 4H. The semiconductor substrate has an n⁺-type first substrate region 301 and an n⁻-type first drain region 302. On the semiconductor substrate, there are formed a switching element, such as a MOSFET 400, and a protection element, such as a pn diode 500 made of, for example, polysilicon carbide. Namely, this embodiment forms the switching element and protection element on the same substrate.

The MOSFET will be explained. At a predetermined location on the surface of the first drain region 302, a p⁻-type base region 303 is formed in contact with a principal plane of the first drain region 302. At a predetermined location on the surface of the base region 303, an n⁺-type first source region 304 is formed. On the surface of the base region 303, an n-type first channel region 305 is formed to connect the first source region 304 and first drain region 302 to each other. On the first channel region 305, a first gate insulating film 306 is formed from, for example, SiO₂. On the first gate insulating film 306, a first gate electrode 307 is formed from, for example, p-type polysilicon carbide, to serve as a drive electrode of the switching element. The first gate insulating film 306 may be made of Si₃N₄. A first source electrode 308 is formed in contact with the first source region 304 and base region 303. On a back face of the semiconductor substrate, a first drain electrode 309 is formed in contact with the first substrate region 301. The MOSFET 400 serving as a switching element has three terminals, i.e., a source terminal, a drain terminal, and a gate terminal. In FIG. 12, the source terminal is represented with “S,” the drain terminal “D,” and the gate terminal “G.”

Next, the pn diode 500 will be explained. The pn diode 500 is insulated from the MOSFET 400 and is formed on an interlayer insulating film 310 made of, for example, SiO₂. The pn diode 500 has an anode region 311 made of p-type polysilicon carbide and a cathode region 312 made of n-type polysilicon carbide. The interlayer insulating film 310 may be made of Si₃N₄. In this case, the pn diode 500 serving as a protection element is made of silicon carbide whose forbidden band gap is wider than silicon. In FIG. 12, two anode regions 311 and two cathode regions 312 are connected in series. The pn diode 500 may be singular, or a plurality of pn diodes 500 may be connected in series. Although not shown in FIG. 12, the anode region 311 is connected to an anode electrode, and the cathode region 312 is connected to a cathode electrode, to provide an output to the outside. In FIG. 12, an anode terminal is represented with “A” and a cathode terminal with “C.”

An example of a method of manufacturing the semiconductor device according to the embodiment will be explained. A semiconductor substrate having an n⁺-type first substrate region 301 on which an n⁻type first drain region 302 is formed is prepared. The concentration and thickness of the first drain region 302 are, for example, 1×10¹⁶ cm⁻³ and 10,,m, respectively. On the surface of the first drain region 302, an LTO (low temperature oxide) film is deposited and is patterned by photolithography and etching to form a mask having a predetermined shape. The mask is used to form a base region 303, a first source region 304, and a first channel region 305 by ion implantation. The ion implantation of the base region 303 is carried out with, for example, aluminum ions, that of the first source region 304 with phosphorus ions, and that of the first channel region 305 with nitride ions, to thereby form the respective conductive regions. The mask is removed, and an activating heat treatment is carried out at 1000° C. or higher to activate the implanted ions. Instead of the ion implantation, the base region 303, first source region 304, and first channel region 305 may epitaxially be grown.

On the semiconductor substrate, an SiO₂ film of a predetermined thickness is formed by, for example, thermal oxidation. This film is used to form a first gate insulating film 306 and an interlayer insulating film 310. According to this embodiment, the first gate insulating film 306 and interlayer insulating film 310 are simultaneously formed to an equivalent thickness. Making the thickness of the interlayer insulating film 310 equal to that of the first gate insulating film 306 can minimize the heat resistance of the interlayer insulating film 310. This results in accurately sensing the temperature of the MOSFET 400, i.e., the switching element. The interlayer insulating film 310 may be thicker than the first gate insulating film 306. For example, the interlayer insulating film 310 may be a layered film made of, for example, an LTO film layer and a thermal oxidation film layer. The first gate insulating film 306 and interlayer insulating film 310 may include a film made of nitride such as Si₃N₄.

After forming the first gate insulating film 306 and interlayer insulating film 310, a PLD (pulse laser deposition) method, for example, is employed to heat the substrate to, for example, 9500C, and p-type polysilicon carbide is formed on the first gate insulating film 306 and interlayer insulating film 310. This p-type polysilicon carbide is used to form a first gate electrode 307, the base of a pn diode 500, and an anode region 311. The forbidden band gap of the polysilicon carbide is wider than that of silicon. At a predetermined position of the pn diode 500, a mask is formed to implant ions such as phosphorus ions to form an n-type cathode region 312.

Next, a mask is patterned at a predetermined location of the polysilicon carbide layer, and the first gate electrode 307 serving as a drive electrode and the pn diode 500 serving as a protection element are simultaneously patterned and formed by, for example, reactive ion etching.

Lastly, a first source electrode 308, an anode electrode (not shown), a cathode electrode (not shown), and a drain electrode 309 are formed to complete the semiconductor device of FIG. 12.

Operation of the semiconductor device according to the eighth embodiment will be explained. First, operation of the pn diode 500 serving as a temperature sensing protection element will be explained. As explained above, the anode and cathode electrodes of the pn diode 500 are connected to a predetermined overheat protection circuit. The overheat protection circuit is configured to supply a predetermined current to the pn diode 500 and observe a potential difference between the terminals of the pn diode 500, or is configured to apply a predetermined voltage to the terminals and observe a current value. The eighth embodiment applies a fixed current between the anode and cathode electrodes of the pn diode 500 and detects a potential difference between the electrodes. The pn diode 500 has a characteristic to change a built-in potential difference depending on an ambient temperature. The overheat protection circuit uses this characteristic to estimate an ambient temperature according to a terminal potential difference of the pn diode 500.

When the switching element, i.e., the MOSFET 400 formed on the same substrate generates heat to heat the substrate, the temperature of the substrate influences a potential difference of the pn diode 500. Therefore, the overheat protection circuit connected to the anode and cathode electrodes of the pn diode 500 can monitor an operating temperature of the MOSFET 400. If the temperature of the MOSFET 400 exceeds a predetermined value, the overheat protection circuit detects it according to a terminal potential difference of the pn diode 500 and issues a signal to suppress the operation of the MOSFET 400, to thereby prevent a breakdown of the MOSFET 400.

The temperature sensing protection element is required to have a function of accurately and correctly detecting a temperature exceeding a preset value, to prevent the switching element from breaking. For this, the eighth embodiment forms the MOSFET 400 serving as a switching element and the pn diode 500 serving as a protection element on the same substrate, to precisely detect the temperature of the switching element. The embodiment forms the pn diode 500 and MOSFET 400 from a wide-gap semiconductor material, to surely demonstrate the temperature detecting function in the entire range of service temperatures of the MOSFET 400.

In addition to the function of surely and correctly detecting an excessive temperature of the switching element, the protection element must be stable not to cause erroneous detection when the switching element is not at excessive temperatures. Erroneous detection will be caused by, for example, electromagnetic noise generated in response to a current change occurring when the MOSFET 400, i.e., the switching element shifts from a conductive state to a nonconductive state, or a potential change in a base region just below the pn diode 500.

According to a conventional structure, it is difficult to increase the insulation capacity of a separation layer between a switching element and a protective pn diode. This is because a conventional protective pn diode made of silicon carbide is formed by separating the switching element and protection element from each other by implanting vanadium ions into a part of a channel epitaxial layer of a junction field effect transistor serving as the switching element. The vanadium ions have a characteristic to form a deeper level relative to silicon carbide semiconductor, and therefore, they can form a semi-insulated region of high resistance compared with a channel region of the switching element. The semi-insulated region, however, has an inferior insulating property compared with an insulating film made of SiO₂ or Si₃N₄ used for standard semiconductor devices. In addition, compared with forming an SiO₂ or Si₃N₄ insulating film by thermal oxidation or deposition, forming an insulating film by injecting vanadium ions is difficult to uniformly control a film thickness and unavoidably causes manufacturing variations that lower an insulation ability.

On the other hand, the eighth embodiment forms the interlayer insulating film 310 from SiO₂ by thermal oxidation and deposits the pn diode 500 on the interlayer insulating film 310. This secures high insulation between the MOSFET 400, i.e., the switching element and the pn diode 500. As a result, variations in the voltage and current of the switching element hardly affect the protection element. Namely, the embodiment can minimize the protection element's erroneous detection without regard to the operating conditions of the MOSFET 400. The eighth embodiment, therefore, can further stabilize the protective function and operate the MOSFET 400 at higher frequencies, higher current densities, and higher voltages.

Operation of the MOSFET 400, i.e., the switching element formed on the same substrate as the protection element will be explained.

For example, the first source electrode 308 is grounded and a positive potential is applied to the first drain electrode 309, to operate the MOSFET 400. If a ground potential, for example, is applied to the first gate electrode 307, the MOSFET 400 is put in a nonconductive or disconnected state. Namely, two built-in potentials due to a work function difference between the first gate electrode 307 and the first channel region 305 and a work function difference between the base region 303 and the first channel region 305 completely deplete the first channel region 305. According to the eighth embodiment, the first gate electrode 307 is made of p-type polysilicon carbide like the pn diode 500. Compared with a gate electrode made of polysilicon, the first gate electrode 307 made of polysilicon carbide has a larger work function difference relative to the first channel region 305, to realize higher cutoff performance. Namely, the MOSFET 400 serving as a switching element can operate at higher temperatures.

When a positive potential is applied to the first gate electrode 307, the depletion layer in the first channel region 305 retracts, and conductive electrons flow from the first source region 304 to the first drain region 302, thereby establishing a conductive state. According to the embodiment, the first channel region 305 becomes a conductive accumulation channel to accumulate electrons due to a gate electric field. This reduces a loss between the first source region 304 and the first drain region 302, and therefore, the MOSFET 400 can operate at higher temperatures.

In this way, employing polysilicon carbide not only for the protection element (pn diode 500) but also for the gate electrode (first gate electrode 307) serving as a drive electrode of the switching element (MOSFET 400) improves the disconnecting and connecting abilities of the switching element and enables the switching element to operate at high temperatures. Consequently, the semiconductor device according to the eighth embodiment is operable in a wide range of service temperatures and hardly causes a breakdown due to overheat.

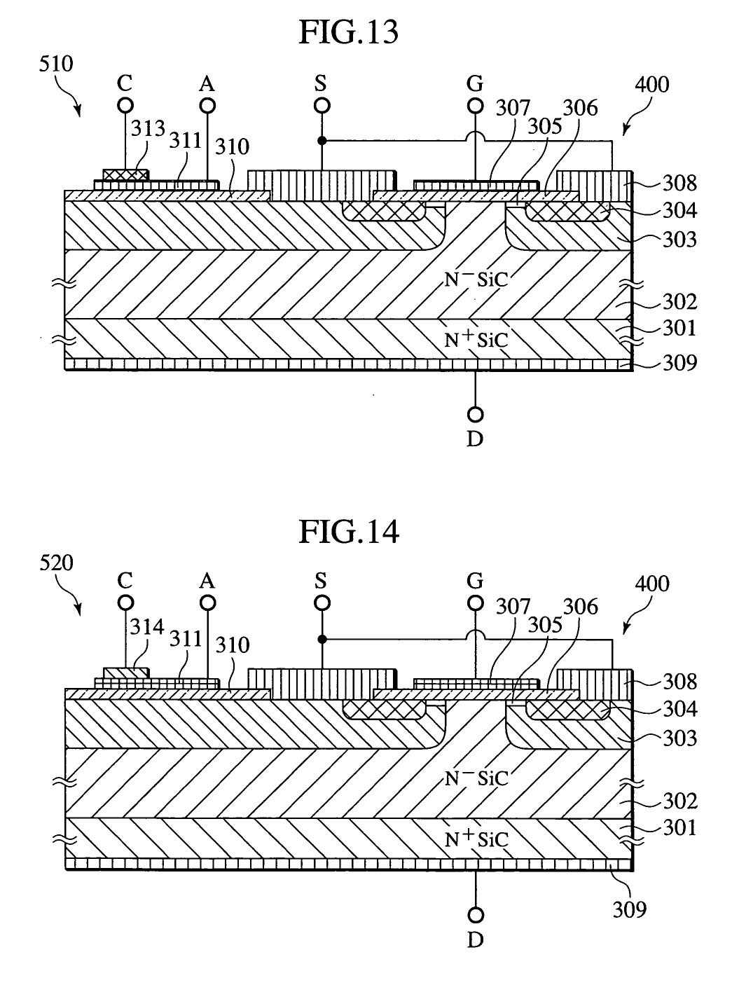

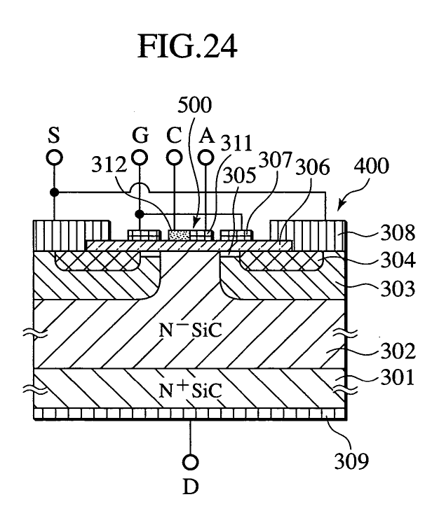

Employing polysilicon carbide to simultaneously forming the protection element and the gate electrode, i.e., the drive electrode of the switching element makes it possible to form the protection element (pn diode 500) adjacent to or just above a conductive path of the switching element (MOSFET 400) as shown in FIG. 13. A part where the switching element generates heat is a part where a current flows in a conductive state. A part which frequently causes an element breakdown due to heat is a surface layer of the switching element where the pn junction and gate insulating film are formed. Accordingly, forming the protection element (pn diode 500) on the surface layer of the switching element (MOSFET 400) as shown in FIG. 24 is effective to more precisely monitor temperatures. The protection element may be formed at a predetermined location to monitor the conductive state of a switching element in a unit area.

According to the eighth embodiment, the pn diode 500 formed on the interlayer insulating film 310 is made of a semiconductor material (polysilicon carbide) whose gap is wider than silicon. Accordingly, the embodiment can easily secure insulation for the MOSFET 400. Namely, the pn diode 500 is not affected by electromagnetic noise or reference potential variations caused by the operating conditions of the MOSFET 400. The eighth embodiment, therefore, can precisely detect the temperature of the MOSFET 400 and can avoid erroneous detection. In addition, the semiconductor device of this embodiment is easy to manufacture.

The interlayer insulating film 310 may be made of SiO₂ having high insulation property, to realize the effect of the present invention through simpler manufacturing processes and at low cost. Employing polysilicon carbide as a semiconductor material realizes the effect of the present invention without complicating manufacturing processes or without increasing cost. The pn diode 500 serving as a protection element can easily realize the above-mentioned effect of the present invention. The pn diode 500 and the first gate electrode 307 of the MOSFET 400 may be made of the same type of semiconductor material (polysilicon carbide) to easily improve the performance of the pn diode 500 and MOSFET 400 without additional manufacturing processes.

The embodiment shown in FIG. 24 forms the pn diode 500 adjacent to a conductive part of the MOSFET 400, to realize high-precision temperature detection. This also realizes the operation monitoring of each unit area. Forming the protection element (pn diode 500) in the vicinity of a conductive part of the switching element (MOSFET 400) is also possible in the below-mentioned embodiments.

The semiconductor base made of silicon carbide according to the embodiment enables the MOSFET 400 to operate at higher frequencies, higher current densities, and higher potential differences. This makes the pn diode 500 fully demonstrate its capacity. According to the embodiment, the interlayer insulating film 310 is first formed, and then, a semiconductor material is deposited on the interlayer insulating film 310. This leads to easily manufacture the semiconductor device of the embodiment. On the semiconductor material, a predetermined mask is formed to simultaneously pattern the pn diode 500 and first gate electrode 307. This simplifies manufacturing processes.

(Ninth Embodiment)

FIG. 13 is a sectional view showing a semiconductor device according to a ninth embodiment of the present invention and corresponds to FIG. 12 of the eighth embodiment. Parts of the ninth embodiment that operate like those of the eighth embodiment will not be explained again, and parts characteristic to the ninth embodiment will be explained in detail.

In FIG. 13, this embodiment is characterized in that a protection element is a Schottky barrier diode 510. Unlike the embodiment of FIG. 12 that employs the pn diode 500 as a protection element, the ninth embodiment employs the Schottky barrier diode 510 as a protection element. The Schottky barrier diode 510 consists of an anode region 311 made of, for example, p⁺-type polysilicon carbide whose forbidden band gap is wider than silicon and a Schottky electrode 313 made of, for example, Ti forming a Schottky connection with the anode region 311.

FIG. 14 is a sectional view showing a semiconductor device according to a modification of the ninth embodiment. In FIG. 14, a heterojunction diode 520 serves as a protection element. Namely, instead of the Schottky electrode 313 of FIG. 13, the modification of FIG. 14 connects a hetero electrode 314 made of, for example, n-type polysilicon instead of polysilicon carbide to an anode region 311.

According to any one of the examples of FIGS. 13 and 14, the protection element, i.e., the diode detects the temperature of a MOSFET 400 serving as a switching element, like the eighth embodiment.

In addition, the ninth embodiment employs the Schottky barrier diode 510 or heterojunction diode 520 as a protection element. In this case, a semiconductor region of the protection element is only the anode region 311, and therefore, only a single kind of impurity material is introduced into the semiconductor region. For example, only polysilicon carbide containing p-type impurities is needed to be deposited. Accordingly, the protection element is manufacturable through simple processes. Although the anode region 311 is of p-type in this embodiment, this does not limit the present invention. The anode region 311 may be of n-type.

The embodiment of FIG. 13 employs the Schottky barrier diode 510 as a protection element. Accordingly, the semiconductor device of this embodiment is easy to manufacture by combining the manufacturing processes of the eighth embodiment with a manufacturing process of the Schottky barrier diode 510. A semiconductor material for this embodiment needs only one kind of impurity material.

The embodiment of FIG. 14 employs the heterojunction diode 520 as a protection element. Accordingly, the semiconductor device of this embodiment is easy to manufacture by combining the manufacturing processes of the eighth embodiment with a manufacturing process of the heterojunction diode 520. A semiconductor material for this embodiment also needs only one kind of impurity material.

(Tenth Embodiment)

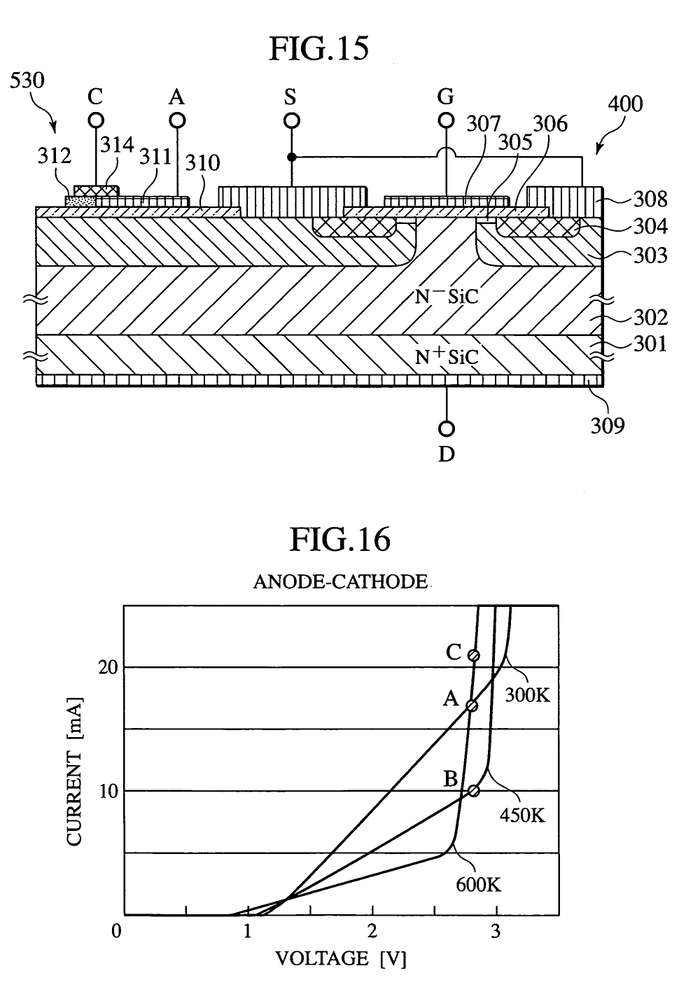

FIG. 15 is a sectional view showing a semiconductor device according to a tenth embodiment of the present invention and corresponds to FIG. 12 of the eighth embodiment. Parts of the tenth embodiment that operate like those of the eighth embodiment will not be explained again, and parts characteristic to the tenth embodiment will be explained in detail. As shown in FIG. 15, this embodiment is characterized by a protection element consisting of a pn junction-heterojunction parallel diode 530 made of a pn diode and a heterojunction diode connected in parallel. According to the embodiment, an anode region 311 made of, for example, p⁺-type polysilicon carbide and a cathode region 312 made of, for example, n⁺-type polysilicon carbide form the pn diode, and the anode region 311 and a hetero electrode 314 made of, for example, n⁺-type polysilicon forming a heterojunction with the anode region 311 form the heterojunction diode that is connected to the pn diode in parallel. According to the embodiment, the cathode region 312 and hetero electrode 314 are each of n⁺-type and a connection between them shows an ohmic characteristic. Namely, the cathode region 312 and hetero electrode 314 are in contact with each other. Instead, they may not be in contact with each other.

FIG. 16 shows an example of a current-voltage characteristic between the anode electrode and the cathode electrode of the pn junction-heterojunction parallel diode 530. When a voltage is applied between the anode and the cathode, the heterojunction diode first operates in the parallel diode 530, to flow a current. As the voltage applied between the anode and the cathode increases, the pn diode also operates to sharply increase a current. This is because the heterojunction diode performs a monopolar operation and the pn diode performs a bipolar operation. A maximum gradient changing point (a point where the gradient of a current curve suddenly changes, i.e., a point where a secondary differential coefficient d2/(dV)² reaches a maximum with I being a current and V a voltage) of the current-voltage characteristic changes according to ambient temperatures as shown in FIG. 16. The temperature characteristics of the maximum gradient changing point of the current-voltage characteristic between the anode electrode and the cathode electrode are useful to monitor temperatures in normal and abnormal operations. For example, an overheat protection circuit connected to the anode and cathode electrodes monitors a terminal current by applying a predetermined voltage to the electrodes. Then, in FIG. 16, a current value between the anode and cathode electrodes changes from A to B to C as temperature rises.

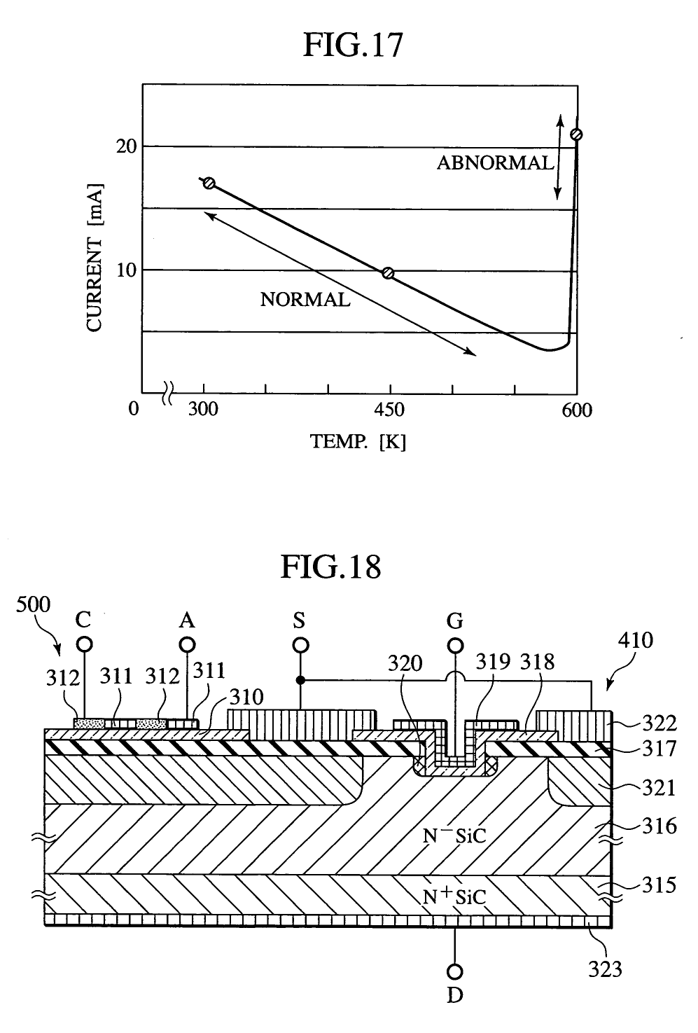

FIG. 17 shows current changes between the anode and cathode electrodes relative to ambient temperatures. When the ambient temperature is between 300K and 450K, the current between the anode and cathode electrodes decreases at a predetermined ratio as the temperature increases. From this, normal operation temperatures will be estimated. When the ambient temperature reaches 600K, the current between the anode and cathode electrodes suddenly increases. A current observed by the overheat protection circuit at this pint is set as a value representative of an abnormal temperature. For example, in FIG. 17, a current value of 20 mA or over is determined to represent abnormal temperatures. In this way, an overheated state is detectable.

The temperature detection zone for a normal operation of the switching element differs from the temperature detection zone above a dangerous temperature to break the switching element. It is, therefore, easy to distinguish a normal operation signal from an abnormal operation signal by inspecting behaviors of the detected signal before and after a detection point, even if the detected signal is affected by electromagnetic noise from the switching element or by reference potential variations. This can prevent erroneous detection.

According to the embodiment, the pn junction and heterojunction are arranged in parallel with each other to form diodes. Instead, a pn junction and a Schottky junction may be formed in parallel, to form a combination of a pn diode and a Schottky diode. This arrangement also provides a protection element to realize the effect of the tenth embodiment of the present invention.

As mentioned above, the semiconductor device according to the tenth embodiment is capable of sensing temperatures at which the MOSFET 400 operates normally and a temperature above which the MOSFET 400 may break. This temperature sensing semiconductor device is usable as a protection device to accurately detect temperatures and correctly determine whether or not a detected signal is affected by electromagnetic noise from the MOSFET 400 or by reference potential variations.

(Eleventh Embodiment)

FIG. 18 is a sectional view showing a semiconductor device according to an eleventh embodiment of the present invention and corresponds to FIG. 12 of the eighth embodiment. Parts of the eleventh embodiment that operate like those of the eighth embodiment will not be explained again, and parts characteristic to the eleventh embodiment will be explained in detail. The eleventh embodiment of FIG. 18 is characterized by a switching element having a different structure from the MOSFET 400. Namely, the switching element of the eleventh embodiment is a heterojunction switch 410 having a second source region 317. More precisely, a second substrate region 315 and a second drain region 316 form a substrate. The second source region 317 is formed in contact with a principal plane of the second drain region 316. The second source region 317 is made of, for example, n-type polysilicon whose forbidden band gap is different from the second drain region 316. Namely, a junction between the second drain region 316 and the second source region 317 is a heterojunction made of silicon carbide and polysilicon having different band gaps. At an interface of the junction, there is an energy barrier. According to this embodiment, the second source region 317 is made of n⁻-type polysilicon. Alternatively, the second source region 317 may be of n⁺-type or of p⁻-type. A second gate insulating film 318 is formed in contact with a contact face between the second source region 317 and the second drain region 316. On the second gate insulating film 318, a second gate electrode 319 is formed from p⁺-type polysilicon carbide. According to the embodiment, the second drain region 316 in contact with the second source region 317 has an n⁺-type low-resistance region 320 that is in contact with the second gate insulating film 318, as well as a p⁺-type field relaxation region 321 that is separated from the second gate insulating film 318. The low-resistance region 320 and field relaxation region 321 may be omitted. A second source electrode 322 is formed in contact with the second source region 317, and a second drain electrode 323 is formed in contact with the second substrate region 315.

In FIG. 18, the eleventh embodiment forms a trench in a surface layer of the drain region 316. In the trench, the second gate insulating film 318 is formed. On the second gate insulating film 318, the second gate electrode 319 is formed. Instead of this trench structure, a planar structure having no trench in the second drain region 316 is also possible.

Operation of the heterojunction switch 410 serving as a switching element will be explained. For example, the second source electrode 322 is grounded and a positive potential is applied to the second drain electrode 323.

For example, a ground potential is applied to the second gate electrode 319, to maintain a nonconductive or disconnected state. This is because an interface at the heterojunction between the second source region 317 and the second drain region 316 forms an energy barrier against conductive electrons.

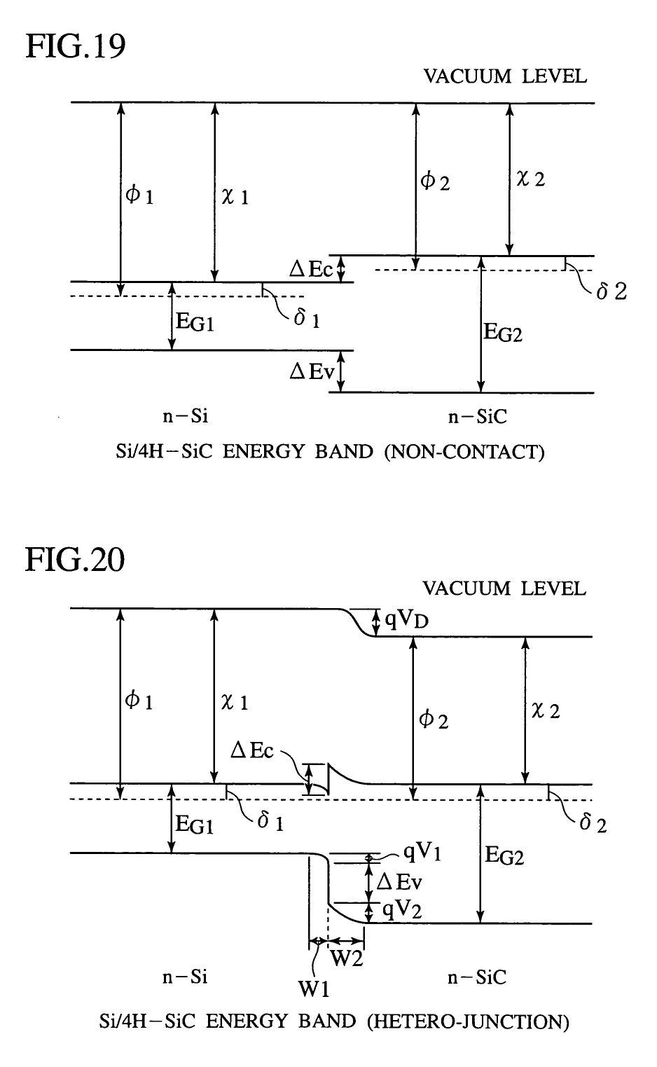

With reference to FIGS. 19 to 23, the characteristics of the heterojunction of polysilicon and silicon carbide will be explained in detail. FIGS. 19 to 23 show semiconductor energy band structures. In each figure, the left side shows an n⁻type silicon energy band structure corresponding to the second source region 317, and the right side shows a 4H n⁻type silicon carbide energy band structure corresponding to the second drain region 316. Although the embodiment forms the second source region 317 from polysilicon, the energy band structures shown in FIGS. 19 to 23 employ silicon. To clearly explain the characteristics of the heterojunction, the below-mentioned explanation is based on the energy level of an ideal semiconductor heterojunction having no interface state at a heterojunction interface.

FIG. 19 shows a state in which silicon and silicon carbide are separated from each other. In FIG. 19, silicon has an electron affinity x₁, a work function φ₁ (energy from a vacuum level to a Fermi level), Fermi energy δ₁ (energy from a conduction band to the Fermi level), and a band gap E_{G1}. Similarly, silicon carbide has an electron affinity x₂, a work function φ2, Fermi energy δ₂, and a band gap E_{G2}. In FIG. 19, a junction face between silicon and silicon carbide involves an energy barrier, Ec due to an electron affinity difference between them and is expressed as follows:
,,Ec=x₁−x₂ (1)

FIG. 20 shows an energy band structure with silicon and silicon carbide being in contact with each other to form a heterojunction of silicon and silicon carbide. After silicon and silicon carbide are made in contact with each other, the energy barrier ,,Ec is present like before the contact. Accordingly, an electron accumulation layer having a width of W1 is formed at a junction interface on the silicon side. On the other hand, a junction interface on the silicon carbide side forms a depletion layer having a width of W1. A diffusion potential generated at each junction interface is V_{D}, a diffusion potential component on the silicon side is V₁, and a diffusion potential component on the silicon carbide side is V₂. Then, qV_{D} (q being elementary charge) is an energy difference between them at a Fermi level, and the relationship is expressed as follows:

$$\begin{matrix}{V}_{D} = ( {δ}_{1} + , , Ec - {δ}_{2} ) / q & ( 2 ) \\ {V}_{D} = {V}_{1} + {V}_{2} & ( 3 ) \\ W2 = \sqrt{\frac{2 {ɛ}_{0} {ɛ}_{2} {V}_{2}}{{qN}_{2}}} & ( 4 )\end{matrix}$$

where ε₀ is a dielectric constant in vacuum, ε₂ is a specific dielectric constant of silicon carbide, and N₂ is an ionization impurity concentration of silicon carbide. These expressions are band discontinuous models based on Anderson electron affinity in an ideal state without considering a distortion effect.

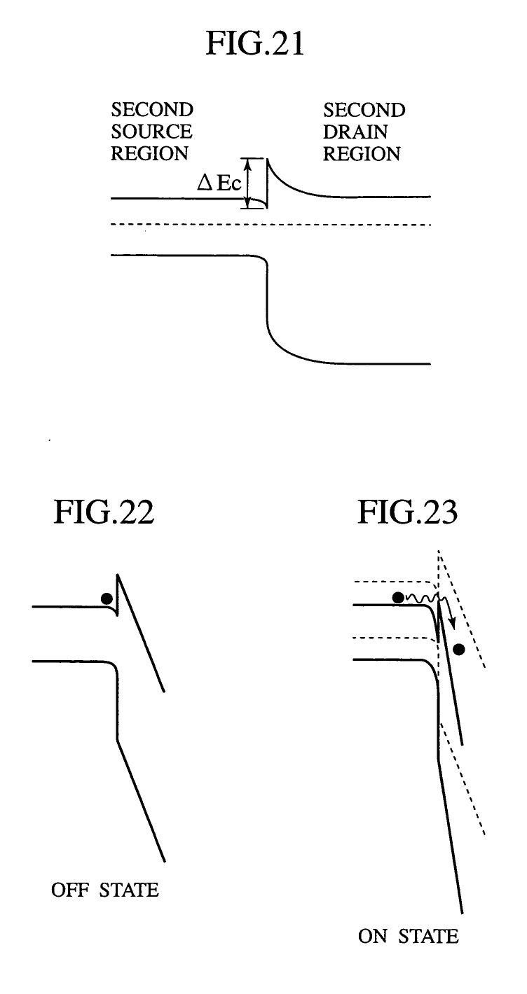

FIGS. 21 to 23 show the energy band structures at the junction interface between the second source region 317 and the second drain region 316 of the embodiment shown in FIG. 18, the second source region 317 being in contact with the second gate electrode 319 through the second gate insulating film 318. In a thermally balanced state with no voltage applied to the second gate electrode 319, second source electrode 322, and second drain electrode 323, the energy band gap structure of FIG. 21 will appear. When the second gate electrode 319 and second source electrode 322 are set at a ground potential and a given positive potential is applied to the second drain electrode 323, the energy band gap structure of FIG. 22 will appear. In FIG. 22, a depletion layer grows from the second drain region 316 side of the heterojunction interface in response to the applied drain potential. On the other hand, conductive electrons present on the second source region 317 side are unable to exceed the energy barrier ,, Ec, and the conductive electrons accumulate at the junction interface. Accordingly, electric force lines corresponding to the depletion layer spreading on the silicon carbide side terminate, and therefore, a drain electric field is shielded on the second source region 317 side. Even if the thickness of polysilicon forming the second source region 317 is very thin, for example, 20 nm, the nonconductive state is maintained. Namely, a withstand voltage is secured. To further improve the cutoff performance, the second source region 317 may be made with a conductivity type or an impurity concentration that achieves a smaller electron density.

According to the embodiment of FIG. 18, a junction between the second source region 318 and the second drain region 316 separated from the second gate electrode 319 has the field relaxation region 321, and therefore, the heterojunction interface around the relaxation region 321 is not exposed to a drain electric field, to improve cutoff performance.

According to the embodiment, the second gate electrode 319 is made of p-type polysilicon carbide, and compared with that of polysilicon, higher cutoff performance is achievable at a junction interface between the second source region 317 and the second drain region 316 around the second gate electrode 319 due to a built-in electric field from the second gate electrode 319. Namely, the heterojunction switch 410 serving as a switching element can also operate at high temperatures.

When a positive potential is applied to the second gate electrode 319 to shift the disconnected state to a conductive state, a gate electric field extends to the heterojunction interface between the second source region 317 and the second drain region 316 through the second gate insulating film 318. As a result, an accumulation layer of conductive electrons is formed in the second source region 317 and second drain region 316 in the vicinity of the second gate electrode 319. Namely, the energy band structure of the junction interface between the second source region 317 and the second drain region 316 close to the second gate electrode 319 changes as indicated with a continuous line shown in FIG. 23. Compared with an energy band structure in an OFF state indicated with a dotted line, potential on the second source region 317 side is pushed down, and the energy barrier on the second drain region 316 side becomes steep. Therefore, conductive electrons can pass through the energy barrier. Consequently, conductive electrons blocked by the energy barrier so far flow from the second source electrode 322 through the second source region 317 in contact with the second gate insulating film 318 to the second drain region 316, to thereby establish a conductive state.

At this time, the embodiment has the low-resistance region 320 at the junction between the second source region 317 and the second drain region 316 adjacent to the second gate electrode 319. This lowers the energy barrier spreading in the second drain region 316, to pass a current with low resistance.

As explained above, the heterojunction switch 410 that is differently structured from the eighth to tenth embodiments can provide the same effect as these embodiments.

Employing polysilicon carbide not only for the pn diode 500 but also for the second gate electrode 319 of the heterojunction switch 410 improves the disconnecting and connecting abilities of the heterojunction switch 410 and enables it to operate at high temperatures. Namely, the semiconductor device of this embodiment can have a wide range of service temperatures and hardly causes a breakdown due to overheat.

According to the eighth to eleventh embodiments, each semiconductor device employs a silicon carbide substrate. Instead, the substrate may be made of any other semiconductor material such as silicon, silicon germane, gallium nitride, or diamond. Each of the embodiments employs a silicon carbide polytype of 4H. The present invention can employ any other silicon carbide polytype such as 6H and 3C. Each of the embodiments arranges a drain electrode and a source electrode to face each other with a drain region interposed between them. This is a vertical structure to vertically pass a drain current. The present invention is also applicable to a horizontal structure to horizontally pass a drain current with a drain electrode and a source electrode arranged on the same principal plane.

According to the eighth to tenth embodiments, the switching element is a MOSFET. The effect of the present invention is not limited by the structure of a switching element. The present invention is applicable to various switching elements including JFETs, bipolar transistors, thyristors, IGBTs, and SITs.

According to the eight to eleventh embodiments, the protection element is made of polysilicon carbide. Other wide-gap semiconductor materials such as gallium nitride and diamond whose gap is wider than silicon are also employable. According to the embodiments, an example of the protection element formed on the same substrate where the switching element is formed is an element having an anode electrode and a cathode electrode that are independently operated to provide a temperature detecting function. The effect of the present invention is also realized with a gate-source overvoltage protection element connected between the gate and source electrodes of the switching element, or a drain-source overvoltage protection element connected between the drain and source electrodes of the switching element. Although the embodiments employ an n-type channel with a drain region being made of n-type silicon carbide, the present invention may employ a p-type channel with a drain region being made of p-type silicon carbide.

The entire contents of Japanese Patent Applications No. 2003-178996 filed on June 24^{th}, 2003, No. 2003-281463 filed on July 29^{th}, 2003, and No. 2003-416247 filed on December 15^{th}, 2003 are hereby incorporated by reference.

Although the invention has been described above by reference to certain embodiments of the invention, the invention is not limited to the embodiments described above. Modifications and variations of the embodiments described above will occur to those skilled in the art, in light of the teachings. The scope of the invention is defined with reference to the following claims.

1. A semiconductor device comprising:
a semiconductor base including:
a semiconductor substrate of a first conductivity type; and
a drain region of the first conductivity type formed on the semiconductor substrate and having a lower impurity concentration than the semiconductor substrate;
a gate electrode insulated from the semiconductor base by a gate insulating film, the gate electrode made of a semiconductor material, a built-in potential difference between a region and the gate electrode made of the semiconductor material is greater than that of polysilicon having as high impurity concentration as possible, the region is a part of the drain region adjacent to the gate electrode through the gate insulating film.

2. The semiconductor device of claim 1, further comprising:
a base region of a second conductivity type formed in a surface area of the drain region and having a predetermined depth;
a source region of the first conductivity type formed in a surface area of the base region and being shallower than the base region;
a surface channel region formed to connect the source region and the drain region to each other;
a source electrode formed in contact with the base and source regions; and
a drain electrode formed at a surface of the semiconductor base.

3. The semiconductor device of claim 2, wherein:
the surface channel region is of the first conductivity type.

4. The semiconductor device of claim 1, wherein:
the gate electrode is made of a semiconductor material having a work function is more than equal to 5.1 eV.

5. The semiconductor device of claim 1, wherein:
the gate electrode is of the second conductivity type.

6. The semiconductor device of claim 1, wherein:
a principal ingredient of the gate electrode is silicon carbide.

7. The semiconductor device of claim 1, wherein:
a principal ingredient of the semiconductor base is silicon carbide.

8. A semiconductor device comprising:
a semiconductor base including:
a semiconductor substrate of a first conductivity type; and
a drain region of the first conductivity type formed on the semiconductor substrate, the drain region having a lower impurity concentration than the semiconductor substrate;
a base region of a second conductivity type formed on a surface of the drain region;
a trench formed adjacent to the base region and reaching the drain region;
a source region of the first conductivity type formed in a predetermined surface area of the base region and shallower than the base region;
a surface channel region formed on an inner side face of the trench, to connect the source and drain regions to each other;
a gate insulating film configured to insulate the semiconductor base from a gate electrode;
the gate electrode formed on the gate insulating film adjacent to the surface channel region from a semiconductor material having a work function of 5.1 eV or over;
a source electrode formed in contact with the base and source regions; and
a drain electrode formed at a surface of the semiconductor base.

9. A semiconductor device comprising:
a semiconductor base including:
a semiconductor substrate of a first conductivity type; and
an epitaxial layer of a second conductivity type formed on the semiconductor substrate and having a lower impurity concentration than the semiconductor substrate;
a source region of the first conductivity type formed on the epitaxial layer and being shallower than the epitaxial layer;
a drain region of the first conductivity type formed on the epitaxial layer and being shallower than the epitaxial layer;
a surface channel region formed to connect the source region and drain region to each other;
a gate insulating film formed on the channel region, the gate insulating film configured to insulate the semiconductor base from a gate electrode;
the gate electrode formed on the gate insulating film adjacent to the surface channel region from a semiconductor material having a work function of 5.1 eV or over;
a source electrode formed in contact with the source region; and
a drain electrode formed in contact with the drain region.

10. A method of manufacturing a semiconductor device, comprising:
forming an epitaxial layer on a semiconductor substrate;
forming a base region in a predetermined area of the epitaxial layer;
forming a surface channel region in a predetermined area on the epitaxial layer and base region;
forming a source region in a predetermined area of the base region;
forming a gate insulating film on the source region and surface channel region; and
forming a gate electrode on the gate insulating film adjacent to the surface channel region from a semiconductor material having a work function of 5.1 eV or over.

11. A semiconductor device comprising:
a drain region of a first conductivity type;
trenches formed in parallel with one another in a principal plane of a semiconductor base where the drain region is formed;
a source region of the first conductivity type formed in contact with a part of the principal plane sandwiched between adjacent ones of the trenches;
insulating films formed in each of the trenches; and
insulated electrodes insulated from the drain region by the insulating film,
wherein the insulated electrode is made of a semiconductor material, a built-in potential difference between a region and the insulated electrode made of the semiconductor material is greater than that of polysilicon having as high impurity concentration as possible, the region is a part of the drain region between the insulated electrodes.

12. The semiconductor device of claim 11, further comprising:
a base region of a second conductivity type formed not in contact with the source region,
wherein the insulated electrode is capable of maintaining at the same potential as the source region.

13. The semiconductor device of claim 12, wherein:
the base region is formed in contact with the principal plane sandwiched between the adjacent trenches and is cable of maintaining at the same potential as at least one of the source region and insulated electrode.

14. The semiconductor device of claim 11, wherein:
the semiconductor material is of the second conductivity type.

15. The semiconductor device of claim 11, wherein:
a principal ingredient of the semiconductor material is silicon carbide.

16. The semiconductor device of claim 11, wherein:
a principal ingredient of the semiconductor base is silicon carbide.

17. A semiconductor device comprising:
a switching unit including a part of a semiconductor base whose forbidden band gap is wider than silicon, the switching unit having at least three terminals;
an insulating film formed on a surface of the semiconductor base; and
a protection unit formed on the insulating film and configured to protect the switching unit, the protection unit made of a semiconductor material whose forbidden band gap is wider than silicon.

18. The semiconductor device of claim 17, wherein:
the insulating film is made of a material selected from the group consisting of an oxide and a nitride.

19. The semiconductor device of claim 17, wherein:
a principal ingredient of the semiconductor material is polysilicon carbide.

20. The semiconductor device of claim 17, wherein:
the protection unit comprises at least one pn diode.

21. The semiconductor device of claim 17, wherein:
the protection unit comprises at least one Schottky diode.

22. The semiconductor device of claim 17, wherein:
the protection unit comprises at least one heterojunction diode.

23. The semiconductor device of claim 17, wherein the protection unit comprises a parallel circuit including:
a pn diode; and
at least one of a Schottky barrier diode and a heterojunction diode connected in parallel to the pn diode.

24. The semiconductor device of claim 23, wherein:
the parallel circuit has a current-voltage characteristic whose maximum gradient changing point changes in response to a change in the ambient temperature.

25. The semiconductor device of claim 17, wherein:
a drive electrode of the switching unit is made of a semiconductor material equivalent to a semiconductor material of the protection unit.

26. The semiconductor device of claim 25, wherein the switching unit comprises:
a first drain region of a first conductivity type formed on the semiconductor base;
a base region of a second conductivity type formed in contact with the first drain region;
a first source region of the first conductivity type formed in contact with the base region; and
a first gate electrode of the second conductivity type serving as the drive electrode formed on a first gate insulating film adjacent to the first source region, the base region, and the first drain region.

27. The semiconductor device of claim 25, wherein the switching element comprises:
a second drain region of the first conductivity type formed on the semiconductor base;
a second source region formed in contact with the second drain region and having a different forbidden band gap from the second drain region; and
a second gate electrode of the second conductivity type serving as the drive electrode formed on a second gate insulating film adjacent to a junction between the second source region and the second drain region.

28. The semiconductor device of claim 25, wherein:
the protection unit is arranged close to a conduction path of the switching element.

29. The semiconductor device of claim 17, wherein:
a principal ingredient of the semiconductor base is silicon carbide.

30. A method of manufacturing a semiconductor device, comprising:
forming a drain region on a semiconductor base;
forming a base region at a surface of the drain region by ion implantation;
forming a source region in contact with the base region;
forming a gate insulating film in contact with the source region, base region, and drain region;
forming a drive electrode on the gate insulating film; and
forming a protection element on the insulating film from a semiconductor material whose forbidden band gap is wider than silicon.

31. The method of claim 30, wherein, when forming a drive electrode on the gate insulating film and forming a protection element on the insulating film from a semiconductor material whose forbidden band gap is wider than silicon:
forming a predetermined mask on the semiconductor material and simultaneously patterning the protection element and drive electrode.
